(19) United States
(12) Patent Application Publication
(10) Pub. No.: US 2025/0208329 A1
(43) Pub. Date: Jun. 26, 2025

(54) OPTICAL FILM, POLARIZING PLATE, COMPOSITION FOR FORMING ALIGNMENT FILM, AND MANUFACTURING METHOD OF POLARIZING PLATE

(71) Applicant: FUJIFILM Corporation, Tokyo (JP)

(72) Inventors: Yuta FUKUSHIMA, Kanagawa (JP); Reiko FUKAGAWA, Kanagawa (JP); Shinpei YOSHIDA, Kanagawa (JP); Yuta TAKAHASHI, Kanagawa (JP)

(73) Assignee: FUJIFILM Corporation, Tokyo (JP)

(21) Appl. No.: 19/075,237

(22) Filed: Mar. 10, 2025

Related U.S. Application Data
(63) Continuation of application No. PCT/JP2023/033059, filed on Sep. 11, 2023.

(30) Foreign Application Priority Data
Sep. 29, 2022 (JP) 2022-156114

(51) Int. Cl. G02B 5/30; C09K 19/04; C09K 19/58; G02B 1/08

(52) U.S. Cl. CPC G02B 5/3016; C09K 19/04; C09K 19/586; G02B 1/08; C09K 2019/0448; C09K 2219/03; C09K 2323/031

(57) ABSTRACT

An optical film which is excellent in ultraviolet absorbability, excellent in aligning properties of a liquid crystal compound in an optically anisotropic layer, and excellent in adhesiveness between an alignment film and an optically anisotropic layer. The optical film includes an alignment film and an optically anisotropic layer disposed adjacent to the alignment film, in which the optically anisotropic layer is formed of a composition containing a liquid crystal compound, the alignment film contains particles containing an ultraviolet absorber and a cured substance of a polymerizable compound having a polymerizable group, an average particle diameter of the particles is 500 nm or less, and a maximal absorption wavelength of the ultraviolet absorber is positioned in a range of 320 to 400 nm.

### CROSS-REFERENCE TO RELATED APPLICATIONS

This application is a Continuation of PCT International Application No. PCT/JP2023/033059 filed on Sep. 11, 2023, which was published under PCT Article 21(2) in Japanese, and which claims priority under 35 U.S.C. § 119(a) to Japanese Patent Application No. 2022-156114 filed on Sep. 29, 2022. The above applications are hereby expressly incorporated by reference, in their entirety, into the present application.

### BACKGROUND OF THE INVENTION

### 1. Field of the Invention

The present invention relates to an optical film, a polarizing plate, a composition for forming an alignment film, and a manufacturing method of a polarizing plate.

### 2. Description of the Related Art

An optically anisotropic layer is used for various applications.

Specific examples of the applications of the optically anisotropic layer include expansion of a viewing angle in an image display apparatus and suppression of coloration.

As the optically anisotropic layer, for example, a layer formed of a liquid crystal compound has been proposed.

In addition, in the image display apparatus, a layer containing an ultraviolet absorber may be provided from the viewpoint of durability and the like of an optical laminate (optical film) including the optically anisotropic layer. For example, JP2021-189224A discloses an optical laminate (optical film) including a positive A layer and an ultraviolet absorbing layer in contact with the positive A layer. In addition, it is also disclosed that the above-described ultraviolet absorbing layer is an alignment film and the positive A layer contains a liquid crystal compound.

### SUMMARY OF THE INVENTION

JP2021-189224A discloses an aspect in which a molecular ultraviolet absorber is used as the ultraviolet absorber contained in the ultraviolet absorbing layer.

The present inventors have found that, in a case where an alignment film containing an ultraviolet absorber is formed with reference to the technique disclosed in JP2021-189224A and an optically anisotropic layer containing a liquid crystal compound is formed on the alignment film, adhesiveness between the alignment film and the optically anisotropic layer may not be sufficient.

In addition, in the optically anisotropic layer formed on the alignment film, it is also required that aligning properties of the liquid crystal compound contained in the optically anisotropic layer are high.

Therefore, an object of the present invention is to provide an optical film which is excellent in ultraviolet absorbability, excellent in aligning properties of a liquid crystal compound in an optically anisotropic layer, and excellent in adhesiveness between an alignment film and an optically anisotropic layer.

Another object of the present invention is to provide a polarizing plate including an optical film, a composition for forming an alignment film, and a manufacturing method of a polarizing plate.

As a result of intensive studies to achieve the above-described objects, the present inventors have found that the above-described objects can be achieved in a case where particles containing a specific ultraviolet absorber and having a particle diameter equal to or smaller than a specific particle diameter are used, and have completed the present invention. That is, the present inventors have found that the above-described objects can be achieved by the following configuration.

[1] An optical film comprising:
an alignment film; and
an optically anisotropic layer disposed adjacent to the alignment film,
in which the optically anisotropic layer is formed of a composition containing a liquid crystal compound,
the alignment film contains particles containing an ultraviolet absorber and a cured substance of a polymerizable compound having a polymerizable group,
an average particle diameter of the particles is 500 nm or less, and
a maximal absorption wavelength of the ultraviolet absorber is positioned in a range of 320 to 400 nm.

[2] The optical film according to [1],
in which the maximal absorption wavelength is positioned in a range of 360 to 400 nm.

[3] The optical film according to [1] or [2],
in which the liquid crystal compound has a polymerizable group, and
both the polymerizable group of the liquid crystal compound and the polymerizable group of the polymerizable compound are radically polymerizable groups, or
both the polymerizable group of the liquid crystal compound and the polymerizable group of the polymerizable compound are cationically polymerizable groups.

[4] The optical film according to any one of [1] to [3],
in which the particles have a polymerizable group, and
both the polymerizable group of the particles and the polymerizable group of the polymerizable compound are radically polymerizable groups, or
both the polymerizable group of the particles and the polymerizable group of the polymerizable compound are cationically polymerizable groups.

[5]A polarizing plate comprising:
the optical film according to any one of [1] to [4]; and
a polarizer.

[6]A composition for forming an alignment film, comprising:
particles containing an ultraviolet absorber; and
a polymerizable compound having a polymerizable group,
in which an average particle diameter of the particles is 500 nm or less, and
a maximal absorption wavelength of the ultraviolet absorber is positioned in a range of 320 to 400 nm.

[7] The composition for forming an alignment film according to [6],
in which the maximal absorption wavelength is positioned in a range of 360 to 400 nm.

[8] The composition for forming an alignment film according to [6] or [7],
in which the particles have a polymerizable group, and
both the polymerizable group of the particles and the polymerizable group of the polymerizable compound are radically polymerizable groups, or
both the polymerizable group of the particles and the polymerizable group of the polymerizable compound are cationically polymerizable groups.

[9]A manufacturing method of a polarizing plate, comprising:
a step of applying the composition for forming an alignment film according to any one of [6] to [8] onto a support to form a first coating film, and subjecting the first coating film to an alignment treatment;
a step of applying a composition containing a liquid crystal compound onto the first coating film subjected to the alignment treatment to form a second coating film;
a step of subjecting the first coating film and the second coating film to a curing treatment for forming an alignment film and an optically anisotropic layer to form a laminate including the support, the alignment film, and the optically anisotropic layer; and
a step of bonding the laminate to a polarizer such that the optically anisotropic layer and the polarizer face each other, and peeling off the support from the obtained bonded body to obtain a polarizing plate including the polarizer, the optically anisotropic layer, and the alignment film.

According to the present invention, it is possible to provide an optical film which is excellent in ultraviolet absorbability, excellent in aligning properties of a liquid crystal compound in an optically anisotropic layer, and excellent in adhesiveness between an alignment film and an optically anisotropic layer.

In addition, according to the present invention, it is possible to provide a polarizing plate including an optical film, a composition for forming an alignment film, and a manufacturing method of a polarizing plate.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

Hereinafter, meaning of each description in the present specification will be explained.

Any numerical range expressed using “to” in the present specification refers to a range including the numerical values before and after the “to” as a lower limit value and an upper limit value, respectively.

In the present specification, Re(λ) and Rth(λ) represent an in-plane retardation at a wavelength λ and a thickness direction retardation at a wavelength λ, respectively. Unless otherwise specified, the wavelength λ is 550 nm.

In the present specification, Re(λ) and Rth(λ) are values measured at the wavelength λ in AxoScan (manufactured by Axometrics, Inc.). By inputting an average refractive index ((nx+ny+nz)/3) and a film thickness (d (μm)) in AxoScan, a slow axis direction (°), Re(λ)=R0(λ), and Rth(λ)=((nx+ny)/2−nz)×d are calculated.

R0(λ) is expressed as a numerical value calculated by AxoScan and represents Re(λ).

In the present specification, the refractive indices nx, ny, and nz are measured using an Abbe refractometer (NAR-4T, manufactured by Atago Co., Ltd.) and using a sodium lamp (λ=589 nm) as a light source. In addition, in a case of measuring the wavelength dependence, it can be measured with a multi-wavelength Abbe refractometer DR-M2 (manufactured by Atago Co., Ltd.) in combination with a dichroic filter.

In addition, values in Polymer Handbook (John Wiley & Sons, Inc.) and catalogs of various optical films can be used. The values of the average refractive index of main optical films are exemplified below: cellulose acylate (1.48), cycloolefin polymer (1.52), polycarbonate (1.59), polymethylmethacrylate (1.49), and polystyrene (1.59).

In addition, in the present specification, a bonding direction of a divalent group (for example, —O—CO—) described is not particularly limited, and for example, in a case where L² in an “L¹-L²-L³” bond is —O—CO—, and a bonding position on the L¹ side is represented by *1 and a bonding position on the L³ side is represented by *2, L² may be *1-O—CO-*2 or *1-CO—O-*2.

In the present specification, “(meth)acrylate” denotes “acrylate” or “methacrylate”, “(meth)acryl” denotes “acryl” or “methacryl”, and “(meth)acryloyl” denotes “acryloyl” or “methacryloyl”.

### <Optical Film>

The optical film according to the embodiment of the present invention includes an alignment film and an optically anisotropic layer disposed adjacent to the alignment film.

As feature points in the optical film according to the embodiment of the present invention, the alignment film contains particles containing an ultraviolet absorber and a cured substance of a polymerizable compound having a polymerizable group, an average particle diameter of the particles is 500 nm or less, and a maximal absorption wavelength of the ultraviolet absorber is positioned in a range of 320 to 400 nm.

A detailed mechanism by which the optical film according to the embodiment of the present invention has excellent ultraviolet absorbability, excellent aligning properties of the liquid crystal compound in the optically anisotropic layer, and excellent adhesiveness between the alignment film and the optically anisotropic layer is not necessarily clear, but the present inventors have presumed as follows.

Since the optical film according to the embodiment of the present invention contains an ultraviolet absorber having a maximal absorption wavelength in a range of 320 to 400 nm, the optical film has excellent ultraviolet absorbability.

On the other hand, in general, polymerization of the polymerizable compound contained in the alignment film is often promoted by ultraviolet rays. Therefore, in a case where the alignment film contains the ultraviolet absorber, the polymerization of the polymerizable compound contained in the alignment film may be inhibited. In a case where molecules of the ultraviolet absorber are uniformly dispersed in the alignment film, it is considered that the polymerization of the polymerizable compound can be uniformly inhibited over the entire alignment film.

Here, in the present invention, since the ultraviolet absorber is contained in the particles, it can be said that the polymerization of the polymerizable compound in a region where the ultraviolet absorber is not present in the vicinity thereof is not likely to be inhibited. In this case, it is considered that the polymerization of the polymerizable compound proceeds in the alignment film, and the adhesiveness between the alignment film and the optically anisotropic layer is excellent.

The particles contained in the alignment film may also be present between the alignment film and a layer of the composition containing a liquid crystal compound, formed on the alignment film. Since the particles do not usually have ability to align the liquid crystal compound, it is considered that a region where the particles are present in the interface thereof may be an alignment defect of the liquid crystal compound. Here, in the present invention, since the average particle diameter of the particles contained in the alignment film is 500 nm or less, it is considered that the region of the alignment defect is small, and as a result, the aligning properties of the liquid crystal compound in the optically anisotropic layer are excellent.

Hereinafter, the configuration of the optical film will be described.

### [Alignment Film]

The alignment film included in the optical film according to the embodiment of the present invention contains particles containing an ultraviolet absorber and a cured substance of a polymerizable compound containing a polymerizable group.

A method for obtaining the alignment film included in the optical film is not particularly limited, and a method of applying a composition for forming an alignment film, which will be described later, onto a support, and performing an alignment treatment and a curing treatment to obtain an alignment film is preferable. Therefore, components contained in the composition for forming an alignment film, which will be described later, and components derived from the components contained in the composition for forming an alignment film may be contained. Components other than the particles containing an ultraviolet absorber and the cured substance of the polymerizable compound having a polymerizable group will be described later.

The alignment film may be a photo-alignment film which exhibits alignment ability of the liquid crystal compound by irradiation with light.

Hereinafter, the alignment film will be described.

### (Particles)

The particles contain an ultraviolet absorber.

It is sufficient that the particles contain an ultraviolet absorber, and the particles may contain a component other than the ultraviolet absorber. In addition, the particles may consist of only a high-molecular-weight-type ultraviolet absorber.

In the present specification, the expression “particles contain an ultraviolet absorber” may be an aspect in which the particles contain a low-molecular-weight ultraviolet absorber or an aspect in which the particles contain a high-molecular-weight ultraviolet absorber. The low-molecular-weight ultraviolet absorber is a compound having ultraviolet absorbing ability but not having a repeating unit. The high-molecular-weight ultraviolet absorber is a polymer compound having a repeating unit including a structure having ultraviolet absorbing ability.

In addition, a state of the ultraviolet absorber contained in the particles is not particularly limited; and the ultraviolet absorber may be uniformly contained in the particles, or may be contained in the particles in a state of being concentrated in a part of the particles. In a case where the ultraviolet absorber is contained in a state of being concentrated in a part of the particles, a large number of parts in which the ultraviolet absorber is concentrated may be present in the particles, or the part in which the ultraviolet absorber is concentrated may be one (for example, a core-shell structure).

The particles also preferably have a polymerizable group, and particularly preferably have a polymerizable group on the surface of the particles. Examples of the polymerizable group include a radically polymerizable group and a cationically polymerizable group.

Details of the components contained in the particles will be described in the section of the composition for forming an alignment film later.

In addition, the average particle diameter of the particles is 500 nm or less.

The average particle diameter of the particles is preferably 20 to 500 nm, more preferably 30 to 450 nm, and still more preferably 50 to 300 nm.

The average particle diameter of the particles is obtained by producing a cross section of the optical film and averaging equivalent circle diameters of cross sections of the particles on the surface of the cross section of the alignment film. Specifically, first, the optical film is subjected to an embedding treatment with an epoxy resin. The optical film subjected to the embedding treatment is cut with an ultramicrotome to obtain a sectioned sample for observation of the optical film.

A carbon vapor deposition treatment is performed on the surface of the obtained sample for observation, as necessary, in order to ensure conductivity of the surface. Thereafter, the obtained sectioned sample is attached in a wire grid shape, and the sample is observed with a transmission electron microscope (TEM) or a scanning transmission electron microscope (STEM). As a TEM device or STEM device, for example, “JEM-F200” manufactured by JEOL Ltd. can be used. The magnification is appropriately changed depending on the observation target, and the observation is performed at a plurality of locations while changing a part to be observed.

In the obtained TEM image or STEM image, the equivalent circle diameter of the cross section of the particle is measured. A length measurement is performed until the number of measured cross sections of the particles reaches 100, and an arithmetic mean thereof is defined as the average particle diameter of the particles. In a case where the number of cross sections of the particles included in one TEM image or STEM image is less than the above-described number, the length measurement is performed in another TEM image or STEM image until the above-described number is reached. In addition, in a case where the image of the particles is unclear in the TEM image or STEM image (for example, in a case where a difference in transmittance of an electron beam between the cured substance of the polymerizable compound of the alignment film and the particles is small), element mapping may be performed using an energy dispersive X-ray spectrometer attached to the TEM device or STEM device, and the particle diameter of the particles may be measured by comparing the element mapping with the TEM image or STEM image.

In addition, the maximal absorption wavelength of the ultraviolet absorber contained in the particles is positioned in a range of 320 to 400 nm. The maximal absorption wavelength of the ultraviolet absorber contained in the particles is preferably positioned in a range of 360 to 400 nm.

The maximal absorption wavelength of the ultraviolet absorber contained in the particles can be measured using a spectrophotometer. More specifically, the alignment film is separated from the optically anisotropic layer, and an absorption spectrum of the alignment film is obtained with a spectrophotometer. Alternatively, an absorption spectrum of a layer other than the alignment film included in the optical film may be measured in advance, and the maximal absorption wavelength of the ultraviolet absorber contained in the particles may be obtained by comparing the absorption spectrum of the layer with the absorption spectrum of the entire optical film.

A content of the particles in the alignment film can be appropriately adjusted depending on the particles used, but from the viewpoint of maintaining the alignment in a favorable state, the content is preferably 0.1% to 30% by mass, more preferably 0.5% to 25% by mass, still more preferably 1% to 20% by mass, particularly preferably 1% to 10% by mass, and most preferably 1% to 5% by mass with respect to the total mass of the alignment film.

### (Cured Substance of Polymerizable Compound)

The cured substance of the polymerizable compound is obtained by curing the polymerizable compound.

The polymerizable compound is a compound having a polymerizable group.

Examples of the polymerizable group included in the polymerizable compound include a radically polymerizable group, a cationically polymerizable group, and an anionically polymerizable group; and a radically polymerizable group or a cationically polymerizable group is preferable. The polymerizable compound may have a plurality of types of polymerizable groups. For example, the polymerizable compound may be a compound having a radically polymerizable group and a cationically polymerizable group.

In a case where the above-described particles have a polymerizable group, it is preferable that both the polymerizable group of the above-described particles and the polymerizable group of the above-described polymerizable compound are radically polymerizable groups, or both the polymerizable group of the above-described particles and the polymerizable group of the above-described polymerizable compound are cationically polymerizable groups. In a case where the above-described requirement is satisfied, the adhesiveness between the alignment film and the optically anisotropic layer is more excellent.

Details of the polymerizable compound will be described in detail in the section of the composition for forming an alignment film later.

A content of the cured substance of the polymerizable compound in the alignment film is preferably 50% to 99.9% by mass, more preferably 60% to 99% by mass, still more preferably 70% to 99% by mass, particularly preferably 80% to 99% by mass, and most preferably 85% to 99% by mass with respect to the total mass of the alignment film.

A thickness of the alignment film is preferably 0.01 to 10 m, more preferably 0.01 to 5 m, and still more preferably 0.01 to 1 m.

### [Optically Anisotropic Layer]

The optically anisotropic layer is a layer formed of a composition containing a liquid crystal compound.

The optically anisotropic layer is preferably a layer formed by fixing an alignment state of the liquid crystal compound. In the layer in which the alignment state of the liquid crystal compound is fixed, optical characteristics derived from the liquid crystal compound are exhibited, and the optical characteristics change depending on the liquid crystal compound and an alignment direction and alignment state of the liquid crystal compound. In the layer in which the alignment state of the liquid crystal compound is fixed, it is sufficient that the alignment state of the liquid crystal compound is fixed, and the liquid crystal compound may no longer have liquid crystallinity.

The alignment state of the liquid crystal compound in the optically anisotropic layer can be appropriately selected depending on the use of the optical film.

Examples of the alignment state of the liquid crystal compound include a nematic alignment (alignment state same as a state in which a nematic phase is formed), a smectic alignment (alignment state same as a state in which a smectic phase is formed), and a cholesteric alignment (alignment state same as a state in which a cholesteric phase is formed).

The alignment direction of the liquid crystal compound may be horizontal with respect to an in-plane direction of the optically anisotropic layer (homogeneous alignment) or may be perpendicular to the in-plane direction of the optically anisotropic layer (homeotropic alignment). In addition, the alignment direction may be inclined from a direction parallel or perpendicular to the in-plane direction of the optically anisotropic layer.

In addition, the alignment direction of the liquid crystal compound may change in a thickness direction of the optically anisotropic layer. For example, in a case where the liquid crystal compound is cholesterically aligned, a pitch of the cholesteric phase may change in the thickness direction of the optically anisotropic layer. Such an optically anisotropic layer is also referred to as a pitch gradient layer. In addition, in a case where the liquid crystal compound is homogeneously aligned, the alignment direction may be a direction in which the alignment direction is inclined from a direction parallel to the in-plane direction of the optically anisotropic layer on one surface of the optically anisotropic layer.

The optically anisotropic layer is formed by fixing a state in which the liquid crystal compound is aligned.

Here, the “fixed” state means a state in which the alignment of the liquid crystal compound is maintained in the alignment state. For example, it is preferable that, in a temperature range of 0° C. to 50° C., under more severe conditions, in a temperature range of −30° C. to 70° C., a state in which the layer has no fluidity and the fixed alignment state can be maintained stably without causing a change in alignment form due to an external field or an external force is preferable. Examples of such a fixing method include a method of aligning a polymerizable liquid crystal compound to form an alignment state, and then performing a curing treatment to react the polymerizable group to fix the alignment state of the liquid crystal compound, as will be described in detail later.

A thickness of the optically anisotropic layer is not particularly limited, but is preferably 0.5 to 10 μm.

Hereinafter, components contained in the composition containing a liquid crystal compound (hereinafter, also referred to as “liquid crystal composition”) will be described.

### (Liquid Crystal Compound)

The type of the liquid crystal compound contained in the liquid crystal composition is not particularly limited.

In general, the types of the liquid crystal compound are classified into a rod-shaped type (rod-like liquid crystal compound) and a disk-shaped type (discotic liquid crystal compound) from the shapes thereof. Furthermore, the liquid crystal compound can be classified into a low-molecular-weight type and a high-molecular-weight type. The term “high-molecular-weight” generally refers to a compound having a degree of polymerization of 100 or more (Polymer Physics-Phase Transition Dynamics, written by Masao Doi, p. 2, published by Iwanami Shoten, 1992). Any liquid crystal compound can be used in the present invention, and it is preferable to use a rod-like liquid crystal compound or a discotic liquid crystal compound, and it is more preferable to use a rod-like liquid crystal compound. Two or more types of rod-like liquid crystal compounds, two or more types of discotic liquid crystal compounds, or a mixture of a rod-like liquid crystal compound and a discotic liquid crystal compound may be used.

The liquid crystal compound may be a polymerizable liquid crystal compound having a polymerizable group. That is, for example, the liquid crystal compound may be a polymerizable rod-like liquid crystal compound or a polymerizable disk-like liquid crystal compound.

The type of the polymerizable group included in the liquid crystal compound is not particularly limited; and a radically polymerizable group or a cationically polymerizable group is preferable, a polymerizable ethylenically unsaturated group or a ring polymerizable group is more preferable, and a (meth)acryloyl group, a vinyl group, a styryl group, an allyl group, or an epoxy group is still more preferable.

Examples of the rod-like liquid crystal compound include liquid crystal compounds described in claim 1 of JP1999-513019A (JP-H11-513019A) and paragraphs 0026 to 0098 of JP2005-289980A.

Examples of the discotic liquid crystal compound include liquid crystal compounds described in paragraphs 0020 to 0067 of JP2007-108732A and paragraphs 0013 to 0108 of JP2010-244038A.

A content of the liquid crystal compound in the liquid crystal composition is not particularly limited, but is preferably 50% by mass or more and more preferably 70% by mass or more with respect to the total mass of the total solid content in the liquid crystal composition. The upper limit thereof is not particularly limited, but is usually 95% by mass or less.

The solid content means a component capable of forming the cured substance, excluding a solvent, and even in a case where a component itself is in a liquid state, such a component is regarded as the solid content.

### (Other Polymerizable Compounds)

The liquid crystal composition may contain other polymerizable compounds having one or more polymerizable groups.

Here, the polymerizable group included in the other polymerizable compounds is not particularly limited, and examples thereof include an acryloyl group, a methacryloyl group, a vinyl group, a styryl group, and an allyl group. Among these, an acryloyl group or a methacryloyl group is preferable.

Examples of the other polymerizable compounds include a non-liquid crystal polymerizable compound. Specific examples thereof include an ester of a polyhydric alcohol and (meth)acrylic acid (for example, ethylene glycol di(meth)acrylate, 1,4-cyclohexane diacrylate, pentaerythritol tetra(meth)acrylate, pentaerythritol tri(meth)acrylate, trimethylolpropane tri(meth)acrylate, trimethylolethane tri(meth)acrylate, dipentaerythritol tetra(meth)acrylate, dipentaerythritol penta(meth)acrylate, dipentaerythritol hexa(meth)acrylate, 1,2,3-cyclohexanetetramethacrylate, polyurethane polyacrylate, polyester polyacrylate, and the like); vinylbenzene and a derivative thereof, vinyl sulfone, acrylamide, and methacrylamide.

In a case where such other polymerizable compounds are contained, a content thereof is preferably less than 50% by mass, more preferably 40% by mass or less, and still more preferably 2% to 30% by mass with respect to the mass of the above-described liquid crystal compound (in a case where there are a plurality of liquid crystal compounds, the total mass of the liquid crystal compounds).

### (Chiral Agent)

The liquid crystal composition may contain a chiral agent.

In a case where the liquid crystal composition contains a chiral agent, the liquid crystal compound can be twisted and aligned along a helical axis. Such an alignment state is also referred to as a cholesteric alignment.

The type of the chiral agent is not particularly limited. Any known chiral agent (for example, described in “Liquid Crystal Device Handbook” edited by the 142nd Committee of the Japan Society for the Promotion of Science, Chapter 3, 4-3, Chiral agents for TN and STN, p. 199, 1989) can be used.

The chiral agent may be a photosensitive chiral agent in which a helical twisting power changes depending on irradiation with light (hereinafter, also simply referred to as “chiral agent A”). The chiral agent A may be liquid crystalline or non-liquid crystalline. The chiral agent A generally has an asymmetric carbon atom in many cases. The chiral agent A may be an axial asymmetric compound or a planar asymmetric compound, which does not have an asymmetric carbon atom.

The chiral agent A may have a polymerizable group.

The chiral agent A may be a chiral agent in which the helical twisting power increases by irradiation with light or a chiral agent in which the helical twisting power decreases by irradiation with light. Among these, a chiral agent in which the helical twisting power decreases by irradiation with light is preferable.

The “increase and decrease in helical twisting power” in the present specification represents an increase or a decrease in helical twisting power in a case where an initial helical direction (helical direction before irradiation with light) of the chiral agent A is defined as “positive”. Accordingly, even in a case where the helical twisting power of the chiral agent continues to decrease to be below zero by irradiation with light and the helical direction is “negative” (that is, even in a case where the chiral agent induces a helix in a helical direction opposite to the initial helical direction (helical direction before irradiation with light)), such a chiral agent also corresponds to the “chiral agent in which the helical twisting power decreases”.

Examples of the chiral agent A include a so-called photoreactive chiral agent. The photoreactive chiral agent is a compound which has a chiral site and has a photoreactive site in which structure changes by irradiation with light, and for example, which greatly changes the twisting power of the liquid crystal compound according to the amount of light irradiated.

Among these, it is preferable that the chiral agent A is a compound having at least a photoisomerization site, and it is more preferable that the photoisomerization site has a photoisomerizable double bond.

In a case where the chiral agent has a photoisomerization group, a pattern having a desired reflection wavelength corresponding to a luminescence wavelength can be formed by irradiation with actinic ray or the like through a photo mask after coating and alignment, which is preferable. The photoisomerizable group is preferably an isomerization moiety of a compound exhibiting photochromic properties, an azobenzene moiety, a cinnamoyl moiety, an α-cyanocinnamoyl moiety, a stilbene moiety, or a chalcone moiety. Specific examples of the compound include compounds described in JP2002-080478A, JP2002-080851A, JP2002-179668A, JP2002-179669A, JP2002-179670A, JP2002-179681A, JP2002-179682A, JP2002-338575A, JP2002-338668A, JP2003-313189A, and JP2003-313292A.

The liquid crystal composition may contain two or more kinds of the chiral agents A, or may contain at least one kind of the chiral agent A and at least one kind of chiral agent in which the helical twisting power does not change by irradiation with light.

A content of the above-described chiral agent A in the liquid crystal composition is not particularly limited, but from the viewpoint that the liquid crystal compound is easily uniformly aligned, the content is preferably 5.0% by mass or less, more preferably 3.0% by mass or less, and still more preferably 2.0% by mass or less with respect to the total mass of the liquid crystal compound. The lower limit of the content of the chiral agent A is not particularly limited, but is preferably 0.01% by mass or more, more preferably 0.02% by mass or more, and still more preferably 0.05% by mass or more with respect to the total mass of the liquid crystal compound.

### (Polymerization Initiator)

The liquid crystal composition may contain a polymerization initiator.

Examples of a polymerization reaction initiated by the polymerization initiator include a thermal polymerization reaction using a thermal polymerization initiator and a photopolymerization reaction using a photopolymerization initiator; and a photopolymerization reaction is more preferable.

Examples of the photopolymerization initiator include α-carbonyl compounds (described in the specifications of U.S. Pat. Nos. 2,367,661A and 2,367,670A), an acyloin ether (described in the specification of U.S. Pat. No. 2,448,828A), an aromatic acyloin compound substituted with α-hydrocarbon (described in the specification of U.S. Pat. No. 2,722,512A), polynuclear quinone compounds (described in the specifications of U.S. Pat. Nos. 3,046,127A and 2,951,758A), a combination of a triaryl imidazole dimer and a p-aminophenyl ketone (described in the specification of U.S. Pat. No. 3,549,367A), acridine and a phenazine compound (described in the specifications of JP1985-105667A (JP-S60-105667A) and U.S. Pat. No. 4,239,850A), an oxadiazole compound (described in the specification of U.S. Pat. No. 4,212,970A), acylphosphine oxide compounds (described in JP1988-040799B (JP-S63-040799B), JP1993-029234B (JP-H5-029234B), JP1998-095788B (JP-H10-095788B), and JP1998-029997B (JP-H10-029997B)), and oxime ester compounds (for example, OXE-01 and OXE-02 manufactured by Omni Inc. and NCI-1919 manufactured by ADEKA CORPORATION).

In a case where the liquid crystal composition contains a polymerization initiator, a content of the polymerization initiator is preferably 0.01% to 20% by mass and more preferably 0.4% to 8% by mass with respect to the total mass of the solid content of the liquid crystal composition.

### (Solvent)

The liquid crystal composition may contain a solvent.

As the solvent, an organic solvent is preferably used.

Examples of the organic solvent include an amide (for example, N,N-dimethylformamide), a sulfoxide (for example, dimethyl sulfoxide), a hydrocarbon (for example, toluene, hexane, or the like), an alkyl halide (for example, chloroform, dichloromethane, or the like), an ester (for example, methyl acetate, butyl acetate, ethyl propionate, or the like), a ketone (for example, acetone, methyl ethyl ketone, cyclohexanone, methyl isobutyl ketone, cyclopentanone, or the like), and an ether (for example, tetrahydrofuran, 1,2-dimethoxyethane, or the like).

Among these organic solvents, an ester or a ketone is preferable.

The solvents may be used alone or in combination of two or more kinds thereof.

### (Other Components)

The liquid crystal composition may contain a component other than the above-described components, and examples thereof include a liquid crystal alignment control agent, an acid generator, a surfactant, a tilt angle control agent, an alignment film interface alignment agent, a plasticizer, and a crosslinking agent.

### [Other Configurations]

The optical film according to the embodiment of the present invention may include other configurations. Examples of the other configurations include a support. Details of the support will be described later.

In a case where the optical film further includes a support, the support is preferably provided on an alignment film side of the optical film.

### <Composition for Forming Alignment Film>

The composition for forming an alignment film according to the embodiment of the present invention contains particles containing an ultraviolet absorber and a polymerizable compound having a polymerizable group, in which an average particle diameter of the particles is 500 nm or less, and a maximal absorption wavelength of the ultraviolet absorber is positioned in a range of 320 to 400 nm.

The above-described alignment film can be formed by applying the composition for forming an alignment film onto a support, and performing an alignment treatment and a curing treatment.

Hereinafter, components contained in the composition for forming an alignment film will be described.

### [Particles]

The particles contained in the composition for forming an alignment film according to the embodiment of the present invention contain an ultraviolet absorber, and the average particle diameter of the particles is 500 nm or less. In addition, the maximal absorption wavelength of the ultraviolet absorber is positioned in a range of 320 to 400 nm.

The average particle diameter of the particles is measured according to the above-described method. Specifically, in the above-described procedure, a film including at least an alignment film formed of the composition for forming an alignment film is used instead of the optical film, and the average particle diameter thereof is measured.

A suitable aspect of the average particle diameter of the particles is the same as the suitable aspect of the average particle diameter of the particles described above.

The maximal absorption wavelength of the ultraviolet absorber contained in the particles is positioned in a range of 320 to 400 nm. The maximal absorption wavelength of the ultraviolet absorber contained in the particles is preferably positioned in a range of 360 to 400 nm.

The maximal absorption wavelength of the ultraviolet absorber contained in the particles is determined according to the above-described method. More specifically, in the above-described procedure, an absorption spectrum of an alignment film formed of the composition for forming an alignment film is obtained using a spectrophotometer.

The maximal absorption wavelength of the ultraviolet absorber contained in the particles may be measured using a dispersion liquid of the particles.

Hereinafter, details of the components contained in the particles will be described.

### (Ultraviolet Absorber)

The particles contained in the composition for forming an alignment film according to the embodiment of the present invention contain an ultraviolet absorber.

As described above, the ultraviolet absorber may be in any of the aspect of the low-molecular-weight ultraviolet absorber or the aspect of the high-molecular-weight ultraviolet absorber.

The maximal absorption wavelength of the ultraviolet absorber is as described above.

The structure having ultraviolet absorbing ability, which is included in the ultraviolet absorber, is not particularly limited as long as it is a structure derived from a compound having a maximal absorption wavelength in the above-described range; and examples thereof include a structure derived from a compound selected from the group consisting of a benzophenone-based compound, a benzoxazinone-based compound, an anthracene-based compound, a benzotriazole-based compound, an indole-based compound, a methine-based compound, a benzodithiol-based compound, and a hydroxyphenyltriazine-based compound. Among these, a structure derived from a benzodithiol-based compound is preferable. The benzodithiol-based compound easily adjusts the maximal absorption wavelength to the above-described preferred range.

As the ultraviolet absorber, a specific polymer including a repeating unit A having a structure represented by Formula (A1) is preferable.

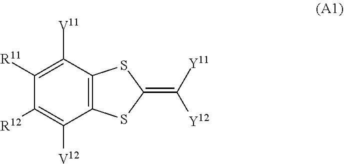

In Formula (A1), one of Y¹¹ or Y¹² represents a cyano group and the other represents a cyano group, an alkylcarbonyl group which may have a substituent, an arylcarbonyl group which may have a substituent, a heterocyclic carbonyl group which may have a substituent, an alkylsulfonyl group which may have a substituent, an arylsulfonyl group which may have a substituent, a carbamoyl group which may have a substituent, a sulfamoyl group which may have a substituent, an alkoxycarbonyl group which may have a substituent, or an aryloxycarbonyl group which may have a substituent.

V¹¹ represents *1-L^{V11}-*2. V¹² represents a hydrogen atom, a monovalent substituent, or *1-L^{V12}-*2. L^{V11} and L^{V12} each independently represent a single bond or a divalent linking group. *1 represents a bonding position to a main chain of the specific polymer. *2 represents a bonding position to a benzene ring specified in Formula (A1).

R¹¹ and R¹² each independently represent a hydrogen atom or a monovalent substituent.

As the alkylcarbonyl group which may have a substituent, represented by Y¹¹ and Y¹², an alkylcarbonyl group having 2 to 8 carbon atoms, which may have a substituent, is preferable; an acetyl group, an ethylcarbonyl group, or a t-butylcarbonyl group is more preferable; and an ethylcarbonyl group or a t-butylcarbonyl group is still more preferable.

As the arylcarbonyl group which may have a substituent, represented by Y¹¹ and Y¹², an arylcarbonyl group having 2 to 14 carbon atoms, which may have a substituent, is preferable; a benzoyl group or a naphthoyl group is more preferable; a benzoyl group is still more preferable.

As the heterocyclic carbonyl group which may have a substituent, represented by Y¹¹ and Y¹², a heterocyclic carbonyl group having 2 to 14 carbon atoms, which may have a substituent, is preferable; a 2-pyridinecarbonyl group or a 2-thiophene carbonyl group is more preferable, and a 2-pyridinecarbonyl group is still more preferable. A heterocyclic ring constituting the above-described heterocyclic carbonyl group may be aromatic or non-aromatic.

As the alkylsulfonyl group which may have a substituent, represented by Y¹¹ and Y¹², an alkylsulfonyl group having 1 to 4 carbon atoms, which may have a substituent, is preferable; and methanesulfonyl is more preferable.

As the arylsulfonyl group which may have a substituent, represented by Y¹¹ and Y¹², an arylsulfonyl group having 6 to 10 carbon atoms, which may have a substituent, is preferable; and benzenesulfonyl is more preferable.

As the carbamoyl group which may have a substituent, represented by Y¹¹ and Y¹², an unsubstituted carbamoyl group or an alkylcarbamoyl group having 1 to 9 carbon atoms, which may have a substituent, is preferable; an unsubstituted carbamoyl group or an alkylcarbamoyl group having 1 to 4 carbon atoms, which may have a substituent, is more preferable; and carbamoyl, N-methylcarbamoyl, N,N-dimethylcarbamoyl, or N-phenylcarbamoyl is still more preferable.

As the sulfamoyl group which may have a substituent, represented by Y¹¹ and Y¹², an alkylsulfamoyl group having 1 to 7 carbon atoms, which may have a substituent, a dialkylsulfamoyl group having 3 to 6 carbon atoms, which may have a substituent, an arylsulfamoyl group having 6 to 11 carbon atoms, which may have a substituent, or a heterocyclic sulfamoyl group having 2 to 10 carbon atoms, which may have a substituent, is preferable; and sulfamoyl, methylsulfamoyl, N,N-dimethylsulfamoyl, phenylsulfamoyl, or 4-pyridinesulfamoyl is more preferable.

As the alkoxycarbonyl group which may have a substituent, represented by Y¹¹ and Y¹², an alkoxycarbonyl group having 2 to 4 carbon atoms, which may have a substituent, is preferable; methoxycarbonyl, ethoxycarbonyl, or (t)-butoxycarbonyl is more preferable; methoxycarbonyl or ethoxycarbonyl is still more preferable; and ethoxycarbonyl is particularly preferable.

As the aryloxycarbonyl group which may have a substituent, represented by Y¹¹ and Y¹², an aryloxycarbonyl group having 6 to 12 carbon atoms, which may have a substituent, is preferable; an aryloxycarbonyl group having 6 to 10 carbon atoms, which may have a substituent, is more preferable; and phenoxycarbonyl, 4-nitrophenoxycarbonyl, 4-acetylaminophenoxycarbonyl, or 4-methanesulfonylphenoxycarbonyl is still more preferable.

Examples of the substituent which can be included in each group represented by Y¹¹ and Y¹² include an alkyl group, an alkoxy group, and an aryl group; and an alkoxy group is preferable.

It is preferable that one of Y¹¹ or Y¹² represents a cyano group and the other represents a cyano group, an alkylcarbonyl group which may have a substituent, an arylcarbonyl group which may have a substituent, a heterocyclic carbonyl group which may have a substituent, a carbamoyl group which may have a substituent, or an alkoxycarbonyl group which may have a substituent; it is more preferable that one of Y¹¹ or Y¹² represents a cyano group and the other represents a cyano group, an alkylcarbonyl group which may have a substituent, an arylcarbonyl group which may have a substituent, a carbamoyl group which may have a substituent, or an alkoxycarbonyl group which may have a substituent; it is still more preferable that one of Y¹¹ or Y¹² represents a cyano group and the other represents a cyano group, an alkylcarbonyl group having 3 to 18 carbon atoms which may have a substituent, an arylcarbonyl group having 7 to 18 carbon atoms which may have a substituent, a carbamoyl group which may have a substituent, or an alkoxycarbonyl group having 3 to 18 carbon atoms which may have a substituent; it is particularly preferable that one of Y¹¹ or Y¹² represents a cyano group and the other represents a cyano group, an ethylcarbonyl group, a t-butylcarbonyl group, a benzoyl group, or an ethoxycarbonyl group; and it is most preferable that Y¹¹ and Y¹² represent a cyano group.

In Formula (A1), V¹¹ represents *1-L^{V11}-*2 L^{V11} represents a single bond or a divalent linking group.

Examples of the divalent linking group represented by L^{V11} include —O—, —S—, —CO—, —COO—, —CONR^{N}—, an alkylene group, an alkenylene group, an arylene group, and a divalent linking group of a combination of these groups. As the divalent linking group of a combination of the groups, —COO-alkylene group-O— or —COO-alkylene group-CO— is preferable; and *1-COO-alkylene group-O-*2 or *1-COO-alkylene group-CO-*2 is more preferable. R^{N} represents a hydrogen atom or a monovalent substituent.

The above-described alkylene group may be linear, branched, or cyclic, and is preferably linear.

The number of carbon atoms in the above-described alkylene group preferably is 1 to 30, more preferably 1 to 10, and still more preferably 1 to 5.

As L^{V11}, *1-X¹—X²—O-*2 or *1-X¹—X²—CO-*2 is also preferable. X¹ and X² have the same meanings as X¹ and X² in Formula (A3), and suitable aspects thereof are also the same.

In Formula (A1), V¹² represents a hydrogen atom, a monovalent substituent, or *1-L^{V12}-*2. L^{V12} represents a single bond or a divalent linking group.

Examples of the monovalent substituent represented by V¹² include a halogen atom, a mercapto group, a cyano group, a carboxy group, a phosphoric acid group, a sulfo group, a hydroxy group, a carbamoyl group, a sulfamoyl group, a nitro group, an alkoxy group, an aryloxy group, an acyl group, an acyloxy group (—OCOR), an acylamino group, a sulfonyl group, a sulfinyl group, a sulfonylamino group, an amino group, an ammonium group, a hydrazino group, a ureido group, an imido group, an alkylthio group, an arylthio group, an alkenylthio group, an alkoxycarbonyl group, an aryloxycarbonyl group, an alkyl group, and an aryl group. The group exemplified as the monovalent substituent represented by V¹² may further have a substituent (for example, a substituent which can be included in Y¹¹ and Y¹²).

As V¹², a cyano group, a nitro group, a hydroxy group, an alkoxy group, an aryloxy group, or an acyloxy group is preferable; an alkoxy group, an aryloxy group, or an acyloxy group is more preferable; an alkoxy group or an acyloxy group is still more preferable; and a methoxy group, an ethoxy group, an i-propyloxy group, a 2-ethylhexyloxy group, a 3,5,5-trimethylhexyloxy group, an acetoxy group, a propionyloxy group, an n-butyloxy group, a t-butyloxy group, a 2-ethylhexyloxy group, a 3,5,5-trimethylhexyloxy group, or a 4-(4-propylcyclohexyl)cyclohexylcarbonyloxy group is particularly preferable.

Examples of the divalent linking group represented by L^{V12} include the divalent linking groups represented by L^{V11}.

As V¹², a monovalent substituent or *1-L^{V12}-*2 is preferable. In addition, in a case where V¹² represents *1-L^{V12}-*2, it is also preferable that L^{V12} represents the same group as L^{V11}.

*1 represents a bonding position to a main chain of the specific polymer. *2 represents a bonding position to a benzene ring specified in Formula (A1).

The benzene ring specified in Formula (A1), which is bonded to the bonding position represented by *2, is a benzene ring constituting benzodithiol in Formula (A1), and is a benzene ring to which V¹¹, V¹², R¹¹, and R¹² are directly bonded.

Hereinafter, *1 and *2 will be described in detail with an example of the specific polymer.

For example, in a case where V¹¹ represents *1-COO—(CH₂)₄—O-*2 and V¹² represents a hydrogen atom, an aspect in which the specific polymer has, as the repeating unit A, a repeating unit represented by Formula (PX) is exemplified as an example of the specific polymer. In addition, in a case where V¹¹ represents *1-COO—(CH₂)₄—O-*2 and V¹² represents *1-COO—(CH₂)₄—O-*2, an aspect in which the specific polymer has, as the repeating unit A, a repeating unit represented by Formula (PY) is exemplified as an example of the specific polymer.

In Formula (PX) and Formula (PY), Y¹¹, Y¹², R¹¹, and R¹² each have the same meaning as each notation in Formula (A1).

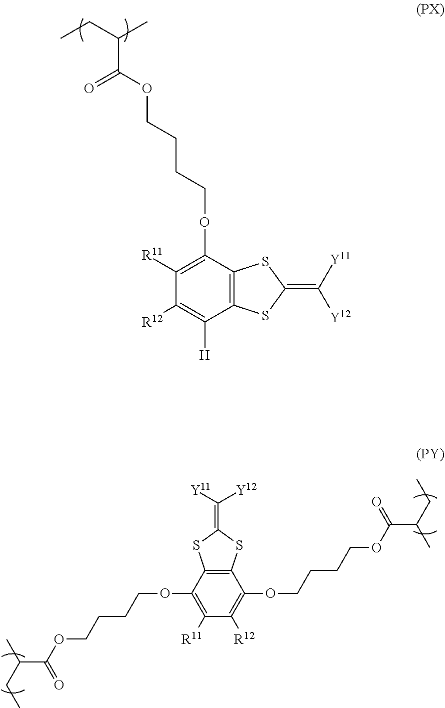

In Formula (A1), R¹¹ and R¹² each independently represent a hydrogen atom or a monovalent substituent.

Examples of the monovalent substituent represented by R¹¹ and R¹² include the monovalent substituents represented by V¹²; and an alkyl group which may have a substituent is preferable, and an unsubstituted alkyl group is more preferable.

The above-described alkyl group may be linear, branched, or cyclic.

The number of carbon atoms in the above-described alkyl group is preferably 1 to 30, more preferably 1 to 10, and still more preferably 1 to 5.

Examples of the above-described alkyl group include a methyl group, an ethyl group, a propyl group, and a butyl group (preferably a t-butyl group).

It is preferable that one of R¹¹ or R¹² represents a hydrogen atom and the other represents a hydrogen atom or an alkyl group which may have a substituent; and it is more preferable that one of R¹¹ or R¹² represents a hydrogen atom and the other represents an alkyl group which may have a substituent.

The repeating unit A preferably has a structure represented by Formula (A2).

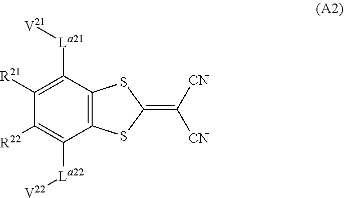

In Formula (A2), V²¹ represents *1-L^{V21}-*2. V²² represents a hydrogen atom, a monovalent substituent, or *1-L^{V22}-*2. L^{V21} and L^{V22} each independently represent a single bond or a divalent linking group. *1 represents a bonding position to a main chain of the specific polymer. *2 represents a bonding position to L^{a21} or L^{a22} specified in Formula (A2).

L^{a21} and L^{a22} each independently represent —O— or —CO—.

R²¹ and R²² each independently represent a hydrogen atom or a monovalent substituent.

In Formula (A2), V²¹ represents *1-L^{V21}-*2. L^{V21} represents a single bond or a divalent linking group.

Examples of the divalent linking group represented by L^{V21} include the divalent linking groups represented by L^{V11}; and —COO-alkylene group- is preferable and *1-COO-alkylene group-*2 is more preferable.

In Formula (A2), V²² represents a hydrogen atom, a monovalent substituent, or *1-L^{V22}-*2. L^{V22} represents a single bond or a divalent linking group.

Examples of the divalent linking group represented by L^{V22} include the divalent linking groups represented by L¹¹; and —COO-alkylene group- is preferable and *1-COO-alkylene group-*2 is more preferable.

In a case where V²² represents *1-L^{V22}-*2, it is also preferable that L^{V22} represents the same group as L^{V21}.

In Formula (A2), L^{a21} and L^{a22} each independently represent —O— or —CO—.

As L^{a21} and L^{a22}, —O— is preferable. In addition, it is also preferable that L^{a21} and L^{a22} represent the same group.

In Formula (A2), R²¹ and R²² have the same meanings as R¹¹ and R¹², and suitable aspects thereof are also the same.

In Formula (A2), meanings of *1 and *2 can be referred to the meanings of *1 and *2 in Formula (A1).

The repeating unit A also preferably has a structure represented by Formula (A3).

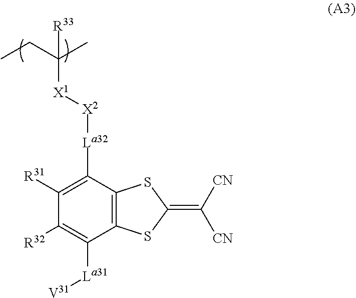

In Formula (A3), V³¹ represents a hydrogen atom, a monovalent substituent, or *1-L^{V31}-*2. L^{V31} represents a single bond or a divalent linking group. *1 represents a bonding position to a main chain of the specific polymer. *2 represents a bonding position to L^{a31} specified in Formula (A3).

L^{a31} and L^{a32} each independently represent —O— or —CO—.

R³¹ and R³² each independently represent a hydrogen atom or a monovalent substituent. R³³ represents a hydrogen atom or a methyl group.

X¹ represents a phenylene group, —COO—, —CONH—, —O—, —CO—, or —CH₂—. X² represents a single bond or a divalent linking group.

V³¹ has the same meaning as V²², and a suitable aspect thereof is also the same.

L^{a31} and L^{a32} have the same meanings as L^{a21} and L^{a22}, and suitable aspects thereof are also the same.

R³¹ and R³² have the same meanings as R¹¹ and R¹², and suitable aspects thereof are also the same.

In Formula (A3), X¹ represents a phenylene group, —COO—, —CONH—, —O—, or —CO—.

As X¹, a phenylene group, —COO—, or —CONH— is preferable, and —COO— is more preferable.

In Formula (A3), X² represents a single bond or a divalent linking group.

Examples of the divalent linking group represented by X² include the divalent linking groups represented by L^{V22}.

It is also preferable that the repeating unit A includes a repeating unit derived from a monomer having at least one polymerizable group selected from the group consisting of a (meth)acrylic group, a styryl group, a (meth)acrylamide group, and a vinyl ether group.

A content of the repeating unit A is preferably 10% to 100% by mass with respect to the total mass of the specific polymer; and from the viewpoint that the effect of the present invention is more excellent, it is more preferably 30% to 100% by mass, still more preferably 40% to 100% by mass, and particularly preferably 50% to 100% by mass.

The specific polymer may have a repeating unit B in addition to the above-described repeating unit A.

The repeating unit B is a repeating unit having a hydrophilic group.

Examples of the hydrophilic group include a carboxylic acid group and a salt thereof, a sulfonic acid group and a salt thereof, a phosphoric acid group and a salt thereof, and a nonionic hydrophilic group such as a hydroxy group, an amino group, a betaine group, an ethylene glycol group, a polyethylene glycol group, a propylene glycol group, a polypropylene glycol group, and an amide group.

The hydrophilic group is preferably at least one group selected from the group consisting of a carboxylic acid group and a salt thereof, a sulfonic acid group and a salt thereof, and a hydroxy group; and more preferably at least one group selected from the group consisting of a carboxylic acid group and a salt thereof, and a sulfonic acid group and a salt thereof.

The number of hydrophilic groups included in the repeating unit B may be 1, or 2 or more.

The repeating unit B is preferably a repeating unit derived from a monomer having a hydrophilic group and a polymerizable group.

As the polymerizable group, an ethylenically unsaturated group is preferable; a vinyl group, a (meth)acryloyl group, a styryl group, or a maleimide group is more preferable; and a vinyl group or a (meth)acryloyl group is still more preferable.

Examples of a monomer having a carboxylic acid group or a salt thereof and a polymerizable group include acrylic acid, methacrylic acid, crotonic acid, itaconic acid, maleic acid, fumaric acid, citraconic acid, 2-methacryloyloxymethyl succinic acid, β-carboxyethyl acrylate, and salts thereof.

Examples of a monomer having a sulfonic acid group or a salt thereof and a polymerizable group include styrene sulfonic acid, 2-acrylamido-2-methylpropanesulfonic acid, 3-sulfopropyl (meth)acrylate, bis-(3-sulfopropyl)-itaconic acid ester, and salts thereof.

Examples of a monomer having a phosphoric acid group or a salt thereof and a polymerizable group include vinylphosphonic acid, vinylphosphate, bis(methacryloxyethyl)phosphate, diphenyl-2-acryloyloxyethyl phosphate, diphenyl-2-methacryloyloxyethyl phosphate, dibutyl-2-acryloyloxyethyl phosphate, and salts thereof.

Examples of a monomer having a nonionic hydrophilic group and a polymerizable group include ethylenically unsaturated monomers having a (poly)ethyleneoxy group or a polypropyleneoxy group, such as 2-methoxyethyl (meth)acrylate, 2-(2-methoxyethoxy)ethyl (meth)acrylate, ethoxytrethyleneglycol (meth)acrylate, methoxypolyethyleneglycol (molecular weight: 200 to 1000) mono(meth)acrylate, and polyethylene glycol (molecular weight: 200 to 1000) mono(meth)acrylate; and ethylenically unsaturated monomers having a hydroxy group, such as hydroxymethyl (meth)acrylate, 2-hydroxyethyl (meth)acrylate, 2-hydroxypropyl (meth)acrylate, 2,3-dihydroxypropyl (meth)acrylate, 4-hydroxybutyl (meth)acrylate, hydroxypentyl (meth)acrylate, and hydroxyhexyl (meth)acrylate.

The repeating unit B preferably has a repeating unit derived from at least one monomer selected from the group consisting of (meth)acrylic acid, itaconic acid, β-carboxyethyl (meth)acrylate, 2-(meth)acrylamide-2-methylpropane sulfonic acid, 3-sulfopropyl (meth)acrylate, salts thereof, and 2,3-dihydroxypropyl (meth)acrylate; more preferably has a repeating unit derived from at least one monomer selected from the group consisting of (meth)acrylic acid, itaconic acid, β-carboxyethyl (meth)acrylate, 2-(meth)acrylamide-2-methylpropane sulfonic acid, 3-sulfopropyl (meth)acrylate, and salts thereof, and still more preferably has a repeating unit derived from at least one monomer selected from the group consisting of (meth)acrylic acid, β-carboxyethyl (meth)acrylate, 2-(meth)acrylamide-2-methylpropane sulfonic acid, 3-sulfopropyl (meth)acrylate, and salts thereof.

Examples of the salt of the carboxylic acid group, the salt of the sulfonic acid group, and the salt of the phosphoric acid group described above include an alkali metal salt (for example, a lithium salt, a sodium salt, a potassium salt, and the like), an alkaline earth metal salt (for example, a barium salt, a calcium salt, and the like), and an ammonium salt; and an alkali metal salt is preferable.

The repeating unit B is preferably a repeating unit represented by Formula (B).

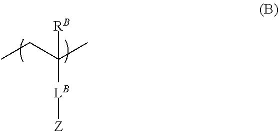

In Formula (B), R^{B} represents a hydrogen atom or a methyl group. L^{B} represents a single bond or a divalent linking group. Z represents a hydrophilic group.

The hydrophilic group represented by Z is as described above.

Examples of the divalent linking group represented by L^{B} include the divalent linking groups represented by L^{V11}; and —COO—, an alkylene group, —CONR^{N}—, or a divalent linking group of a combination of these groups is preferable. The substituent which can be included in the above-described alkylene group is preferably the hydrophilic group included in the repeating unit B, and more preferably a hydroxy group. R^{N} represents a hydrogen atom or a monovalent substituent.

In a case where the specific polymer has the repeating unit B, a content of the repeating unit B is preferably 1% to 90% by mass, more preferably 1% to 70% by mass, still more preferably 1% to 50% by mass, particularly preferably 5% to 40% by mass, and most preferably 7% to 30% by mass with respect to the total mass of the specific polymer.

The specific polymer may have a repeating unit C other than the repeating unit A and the repeating unit B.

Examples of the repeating unit C include a repeating unit derived from an alkyl (meth)acrylate.

A weight-average molecular weight of the specific polymer is preferably 1,000 to 500,000, more preferably 1,000 to 100,000, still more preferably 1,000 to 500,000, and particularly preferably 3,000 to 50,000.

A content of the ultraviolet absorber with respect to the total mass of the particles is preferably 5% to 100% by mass and more preferably 20% to 100% by mass with respect to the total mass of the particles.

In a case where the ultraviolet absorber is the high-molecular-weight ultraviolet absorber, a content of the repeating unit having ultraviolet absorbing ability is preferably 5% to 100% by mass and more preferably 20% to 100% by mass with respect to all repeating units of the high-molecular-weight ultraviolet absorber.

### (Binder)

The particles may contain a binder as a component other than the ultraviolet absorber. The binder is not particularly limited, and examples thereof include an acrylic resin, a urethane resin, a styryl resin, a silicon resin, an epoxy resin, an ester resin, and a diene-based polymer; and an acrylic resin is preferable.

### (Polymerizable Group)

The particles may have a polymerizable group, and it is preferable that the particles have a polymerizable group on a surface thereof. Examples of the polymerizable group include a radically polymerizable group and a cationically polymerizable group. Examples of the radically polymerizable group and the cationically polymerizable group are the same as those of the polymerizable compound described later.

In the above-described aspect, it is sufficient that the polymerizable group is present in the particles, and the polymerizable group may be bonded to the ultraviolet absorber or may be bonded to a component other than the ultraviolet absorber (for example, the binder).

In addition, examples of a method for obtaining the particles having a polymerizable group include a method of obtaining particles using an ultraviolet absorber having a polymerizable group, a method of obtaining particles using a binder having a polymerizable group, and a method of modifying a surface of particles not having a polymerizable group with a compound having a polymerizable group.

As the particles containing an ultraviolet absorber, a commercially available product may be used.

Examples of the commercially available product include Tinuvin (registered trademark; the same applies hereinafter) DW series (Tinuvin 400-DW, Tinuvin 477-DW, Tinuvin 479-DW, Tinuvin 49945-DW, Tinuvin 123-DW, Tinuvin 249-DW, and the like) manufactured by BASF SE, and SE-2915E manufactured by Taisei Fine Chemical Co., Ltd.

Examples of a method for obtaining the particles containing an ultraviolet absorber include a method of, in a case where the ultraviolet absorber is the specific polymer, precipitating the specific polymer to obtain a solid, and then pulverizing the solid with a ball mill, a roll mill, or the like. Examples of a method of precipitating the specific polymer include a method of dissolving the specific polymer in a good solvent and then bringing the solution into contact with a poor solvent, and a method of removing a solvent component from a solution containing the specific polymer.

In addition, the particles containing an ultraviolet absorber can be obtained by a method of forming self-dispersed particles by a phase-transfer emulsification method.

The method for producing the particles containing an ultraviolet absorber is not particularly limited, but the particles are preferably particles obtained by a phase-transfer emulsification method.

In the phase-transfer emulsification method, for example, first, the ultraviolet absorber (for example, the specific polymer) is dissolved or dispersed in a solvent (for example, a water-soluble organic solvent). Next, a method of adding the ultraviolet absorber to water without adding a surfactant, and stirring and mixing the ultraviolet absorber in a state in which a group capable of forming a salt of the ultraviolet absorber (for example, an acidic group) is neutralized, and then removing the solvent can be mentioned. According to the above-described procedure, an aqueous dispersion of the particles containing an ultraviolet absorber is obtained.

A content of the particles is preferably 0.1% to 30% by mass, more preferably 0.5% to 25% by mass, still more preferably 1% to 20% by mass, particularly preferably 1% to 10% by mass, and most preferably 1% to 5% by mass with respect to the total solid content of the composition for forming an alignment film.

The particles may be used alone or in combination of two or more kinds thereof.

In a case where two or more kinds of the particles are used, the total amount thereof is preferably within the above-described preferred content range.

### [Polymerizable Compound]

The polymerizable compound is a compound having a polymerizable group.

Examples of the polymerizable group included in the polymerizable compound include a radically polymerizable group, a cationically polymerizable group, and an anionically polymerizable group; and a radically polymerizable group or a cationically polymerizable group is preferable. The polymerizable compound may have a plurality of types of polymerizable groups. For example, the polymerizable compound may be a compound having a radically polymerizable group and a cationically polymerizable group.

As the radically polymerizable group, a generally known radically polymerizable group can be used, and an acryloyloxy group or a methacryloyloxy group is preferable.

As the cationically polymerizable group, a generally known cationically polymerizable group can be used; and examples thereof include an alicyclic ether group, a cyclic acetal group, a cyclic lactone group, a cyclic thioether group, a spiroorthoester group, and a vinyloxy group. Among these, an alicyclic ether group or a vinyloxy group is preferable, and an epoxy group, an oxetanyl group, or a vinyloxy group is more preferable.

The polymerizable compound may be a polymer having a repeating unit, or a compound not having a repeating unit.

In a case where the polymerizable compound is a polymer having a repeating unit, examples of the polymerizable compound include a polyvinyl alcohol-based resin, a polyimide-based resin, a (meth)acrylic resin, a siloxane-based resin, and a cycloolefin-based resin. Among these, a vinyl alcohol-based resin or a (meth)acrylic resin is preferable, and a vinyl alcohol-based resin is more preferable.

Examples of the polymerizable compound as a vinyl alcohol-based resin include a polymerizable compound represented by General Formula (I).

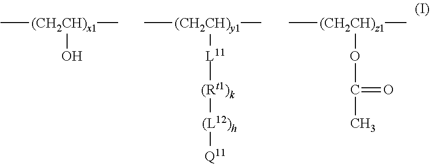

In Genera Formula (I), L¹¹ represents an ether bond, a urethane bond, or an ester bond.

In General Formula (I), R^{t1} represents an alkylene group or an alkylenoxy group.

In General Formula (I), L¹² represents a linking group bonding R^{t1} and Q¹¹.

In General Formula (I), Q¹¹ represents a polymerizable group.

In General Formula (I), under a condition of x1+y1+z1=100, x1 is 10 to 99.9 mol %, y1 is 0.01 to 80 mol %, and z1 is 0 to 70 mol %. x1 is preferably 50 to 99.9 mol %. y1 is preferably 0.01 to 50 mol %, more preferably 0.01 to 20 mol %, still more preferably 0.01 to 10 mol %, and particularly preferably 0.01 to 5 mol %. z1 is preferably 0.01 to 50 mol %.

In General Formula (I), k and h each independently represent an integer of 0 or 1.

In General Formula (I), R^{t1} preferably represents an alkylene group having 1 to 24 carbon atoms, and more preferably represents an alkylene group having 1 to 12 carbon atoms.

A methylene group included in R^{t1} may be substituted with one or more selected from the group consisting of —O—, —CO—, —NH—, —NR⁷— (R⁷ represents an alkyl group having 1 to 4 carbon atoms or an aryl group having 6 to 15 carbon atoms), —S—, and —SO₂—.

L¹² preferably represents —O—, —S—, —CO—, —O—CO—, —O—CO—O—, —CO—O—CO—, —CONR—, —NR—, —NRCONR—, or —NRCO—O— (here, R represents a hydrogen atom or an alkyl group having 1 to 4 carbon atoms).

-(L¹²)ₕ-Q¹² preferably represents a vinyl group, a vinyloxy group, an acryloyl group, a methacryloyl group, a crotonoyl group, an acryloyloxy group, a methacryloyloxy group, a crotonoyloxy group, a vinylphenoxy group, a vinylbenzoyloxy group, a styryl group, a 1,2-epoxyethyl group, a 1,2-epoxypropyl group, a 2,3-epoxypropyl group, a 1,2-iminoethyl group, a 1,2-iminopropyl group, or a 2,3-iminopropyl group.

-(L¹²)ₕ-Q¹² more preferably represents a vinyl group, a vinyloxy group, an acryloyl group, a methacryloyl group, an acryloyloxy group, a methacryloyloxy group, a crotonoyloxy group, a vinylbenzooyloxy group, a 1,2-epoxyethyl group, a 1,2-epoxypropyl group, a 2,3-epoxypropyl group, a 1,2-iminoethyl group, a 1,2-iminopropyl group, or a 2,3-iminopropyl group; and still more preferably represents an acryloyl group, a methacryloyl group, an acryloyloxy group, or a methacryloyloxy group.

Examples of the polymerizable compound as a vinyl alcohol-based resin also include a polymerizable compound represented by General Formula (III).

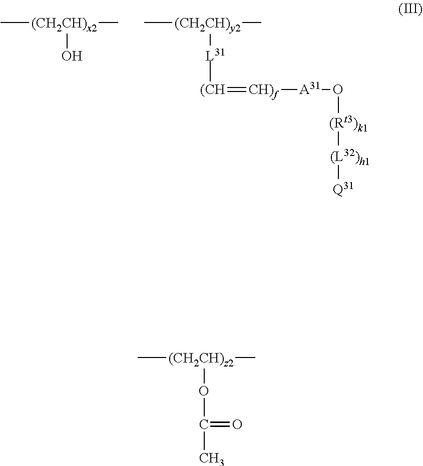

In Formula (III), L³¹ represents an ether bond, a urethane bond, or an ester bond.

In Formula (III), A³¹ represents an arylene group which may have a substituent. Examples of the substituent which may be included in the arylene group include one or more groups selected from the group consisting of a halogen atom, an alkyl group, and an alkoxy group. A³¹ is preferably an arylene group having 6 to 24 carbon atoms, or an arylene group having 6 to 24 carbon atoms, which is substituted with one or more substituents selected from the group consisting of a halogen, an alkyl group having 1 to 4 carbon atoms, and an alkoxy having 1 to 4 carbon atoms.

In Formula (III), R^{t1} represents the same group as R^{t1}.

In Formula (III), L³² represents the same group as L¹².

In Formula (III), Q³¹ represents the same group as Q¹¹.

In Formula (III), under a condition of x2+y2+z2=100, x2 is 10 to 99.9 mol %, y2 is 0.01 to 80 mol %, and z2 is 0 to 70 mol %. x2 is preferably 50 to 99.9 mol %. y2 is preferably 0.01 to 50 mol %, more preferably 0.01 to 20 mol %, still more preferably 0.01 to 10 mol %, and particularly preferably 0.01 to 5 mol %. z2 is preferably 0.01 to 50 mol %.

In Formula (III), kl and hi each represent an integer of 0 or 1.

In Formula (III), f represents an integer of 0 or 1.

In addition, it is also preferable that a hydrogen atom of a hydroxy group included in the repeating unit with the subscript of x1 in General Formula (I) or a hydrogen atom of a hydroxy group included in the repeating unit with the subscript of x2 in General Formula (III) is substituted with a repeating unit represented by Formula (II).

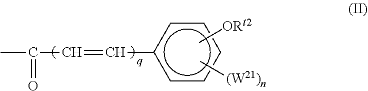

In Formula (II), R^{t2} represents an alkyl group, or an alkyl group substituted with an alkoxy group, an allyl group, a halogen atom, a vinyl group, a vinyloxy group, an oxiranyl group, an acryloyloxy group, a methacryloyloxy group, or a crotonoyloxy group.

In Formula (II), W²¹ represents an alkyl group or an alkoxy group. The alkyl group may be substituted with an alkoxy group, an aryl group, a halogen atom, a vinyl group, a vinyloxy group, an oxiranyl group, an acryloyloxy group, a methacryloyloxy group, or a crotonoyloxy group. The alkoxy group may be substituted with an alkyl group, an alkoxy group, an aryl group, a halogen atom, a vinyl group, a vinyloxy group, an oxiranyl group, an acryloyloxy group, a methacryloyloxy group, or a crotonoyloxy group.

In Formula (II), q represents an integer of 0 or 1.

In Formula (II), n represents an integer of 0 to 4, preferably represents 0 or 1 and more preferably represents 0.

In a case where the polymerizable compound represented by General Formula (I) or General Formula (III) has the repeating unit having a group of General Formula (II), the repeating unit having a group of General Formula (II) is preferably in a range of 0.1% to 10 mol % and more preferably in a range of 0.1 to 5 mol % with respect to all repeating units of the compound represented by General Formula (I) or General Formula (III).

In a case where the polymerizable compound is a vinyl alcohol-based resin, polymerizable compounds described in JP1997-152509A (JP-H09-152509A) can also be suitably used.

In addition, the above-described document can be referred to for a method of synthesizing the polymerizable compound represented by General Formula (I) or General Formula (III).

In a case where the alignment film is a photo-alignment film, the polymerizable compound preferably has a repeating unit having a photo-aligned group. As the photo-aligned group, a group in which at least one of dimerization or isomerization occurs by action of light is preferable.

Suitable specific examples of the group which is dimerized by the action of light include groups having a skeleton of at least one derivative selected from the group consisting of a cinnamic acid derivative, a coumarin derivative, a chalcone derivative, a maleimide derivative, and a benzophenone derivative.

On the other hand, suitable specific examples of the group which is isomerized by the action of light include groups having a skeleton of at least one compound selected from the group consisting of an azobenzene compound, a stilbene compound, a spiropyran compound, a cinnamic acid compound, and a hydrazono-β-ketoester compound.

Among such photo-aligned groups, a group having a skeleton of at least one derivative or compound selected from the group consisting of a cinnamic acid derivative, a coumarin derivative, a chalcone derivative, a maleimide derivative, an azobenzene compound, a stilbene compound, and a spiropyran compound is preferable; and among these, a group having a skeleton of a cinnamic acid derivative or an azobenzene compound is more preferable, and a group having a skeleton of a cinnamic acid derivative (hereinafter, also abbreviated as a “cinnamoyl group”) is still more preferable.

As the polymerizable compound having a repeating unit having a photo-aligned group, a copolymer having a repeating unit AX represented by Formula (A) and a repeating unit BX represented by Formula (B) is preferable.

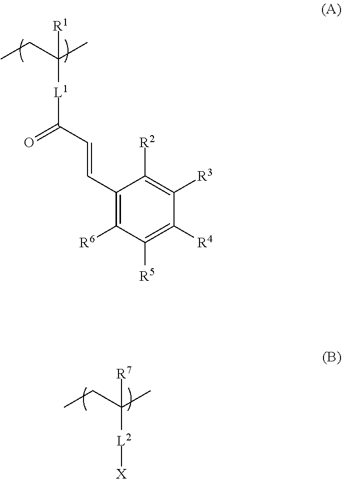

In Formula (A), R¹ represents a hydrogen atom or a methyl group. L¹ represents a divalent linking group. R², R³, R⁴, R⁵, and R⁶ each independently represent a hydrogen atom or a substituent, and two adjacent groups among R², R³, R⁴, R⁵, and R⁶ may be bonded to form a ring.

In Formula (B), R⁷ represents a hydrogen atom or a methyl group, L² represents a divalent linking group, and X represents a polymerizable group.

In Formula (A), L¹ represents a divalent linking group.

L¹ is preferably a divalent linking group obtained by combining at least two or more groups selected from the group consisting of a linear, branched, or cyclic alkylene group having 1 to 18 carbon atoms, which may have a substituent, an arylene group having 6 to 12 carbon atoms, which may have a substituent, an ether group (—O—), a carbonyl group (—C(═O)—), and an imino group (—NH—) which may have a substituent.

L¹ also preferably represents a divalent linking group including a nitrogen atom and a cycloalkane ring, and a part of carbon atoms constituting the cycloalkane ring may be substituted with a heteroatom selected from the group consisting of nitrogen, oxygen, and sulfur.

From the viewpoint of further improving the liquid crystal alignment properties, it is also preferable that L¹ in Formula (A) is a divalent linking group represented by any one of Formulae (1) to (10).

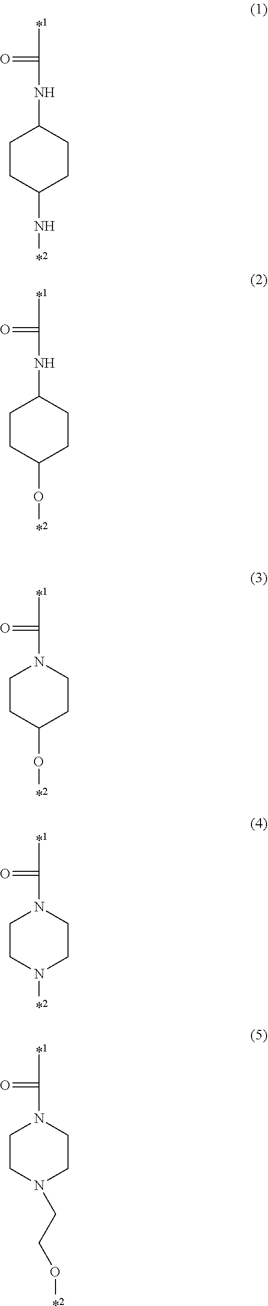

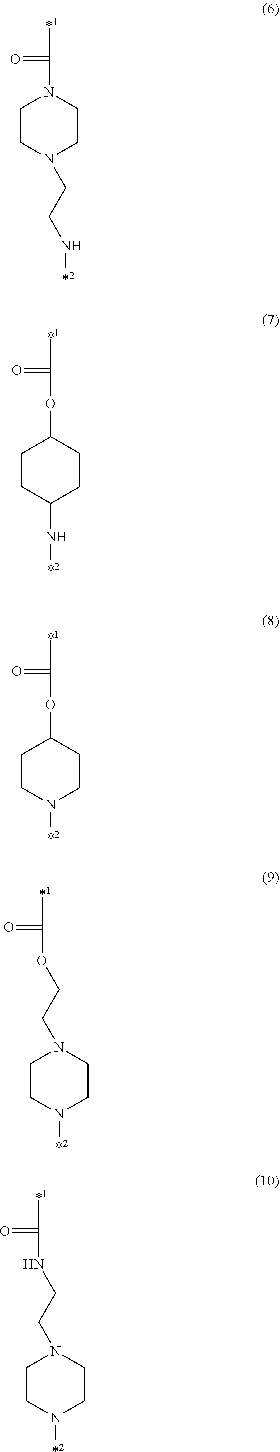

In Formulae (1) to (10), *1 represents a bonding position to a carbon atom constituting the main chain in Formula (A) described above, and *2 represents a bonding position to a carbon atom constituting the carbonyl group in Formula (A) described above.

Next, the substituents represented as an aspect of R², R³, R⁴, R⁵, and R⁶ in Formula (A) will be described. R², R³, R⁴, R⁵, and R⁶ in Formula (A) may represent a hydrogen atom in place of the substituent, as described above.

From the reason that the photo-aligned group is easy to interact with the liquid crystal compound, and thus the liquid crystal alignment properties are further improved, the substituents represented as an aspect of R², R³, R⁴, R⁵, and R⁶ in Formula (A) each independently preferably represent a halogen atom, a linear, branched, or cyclic alkyl group having 1 to 20 carbon atoms, a linear halogenated alkyl group having 1 to 20 carbon atoms, an alkoxy group having 1 to 20 carbon atoms, an aryl group having 6 to 20 carbon atoms, an aryloxy group having 6 to 20 carbon atoms, a cyano group, an amino group, or a group represented by Formula (11).

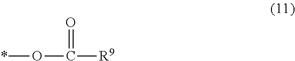

Here, in Formula (11), * represents a bonding position to the benzene ring in Formula (A) described above, and R⁹ represents a monovalent organic group.

Examples of the monovalent organic group represented by R⁹ include a linear or cyclic alkyl group having 1 to 20 carbon atoms.

The linear alkyl group is preferably an alkyl group having 1 to 6 carbon atoms; and specific examples thereof include a methyl group, an ethyl group, and an n-propyl group, and among these, a methyl group or an ethyl group is preferable.

The cyclic alkyl group is preferably an alkyl group having 3 to 6 carbon atoms; and specific examples thereof include a cyclopropyl group, a cyclopentyl group, and a cyclohexyl group, and among these, a cyclohexyl group is preferable.

As the monovalent organic group represented by R⁹ in Formula (11), a combination of a plurality of the above-described linear alkyl groups and a plurality of the above-described cyclic alkyl groups bonded directly or through a single bond may be used.

It is also preferable that R⁴ is the group represented by Formula (11).

In Formula (B), L² represents a divalent linking group.

Examples of the divalent linking group represented by L² include the same groups as those described for the divalent linking group represented by L¹ in Formula (A) above.

In Formula (B), X represents a polymerizable group.

Specific examples of X (polymerizable group) in Formula (B) include an epoxy group, an epoxycyclohexyl group, an oxetanyl group, and a functional group having an ethylenically unsaturated double bond; and among these, at least one polymerizable group selected from the group consisting of groups represented by Formulae (X1) to (X4) is preferable.

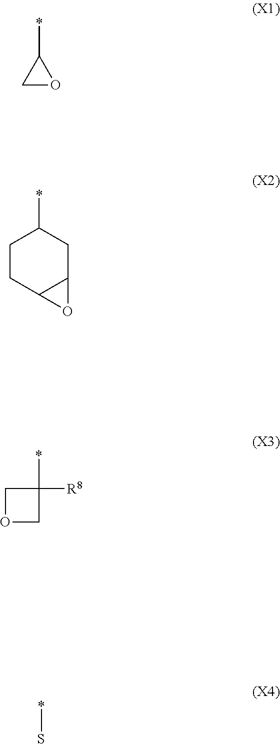

In Formulae (X1) to (X4), * represents a bonding position to L² in Formula (B) described above, and R⁸ represents a hydrogen atom, a methyl group, or an ethyl group. In Formula (X4), S represents a functional group having an ethylenically unsaturated double bond.

Here, specific examples of the functional group having an ethylenically unsaturated double bond include a vinyl group, an allyl group, a styryl group, an acryloyl group, and a methacryloyl group; and an acryloyl group or a methacryloyl group is preferable.

The polymerizable compound having the repeating unit having a photo-aligned group may have a repeating unit other than the repeating unit AX and the repeating unit BX described above.

Examples of a monomer (radically polymerizable monomer) forming the repeating unit other than the above-described repeating units include an acrylic acid ester compound, a methacrylic acid ester compound, a maleimide compound, an acrylamide compound, acrylonitrile, maleic acid anhydride, a styrene compound, and a vinyl compound.

A method of synthesizing the above-described copolymer is not particularly limited, and for example, the copolymer can be synthesized by mixing a monomer forming the above-described repeating unit A, a monomer forming the above-described repeating unit B, and a monomer forming any other repeating units, and polymerizing the mixture in an organic solvent using a radically polymerization initiator.

A weight-average molecular weight (Mw) of the above-described copolymer is preferably 10,000 to 500,000 and more preferably 10,000 to 100,000.

Here, the weight-average molecular weight and the number-average molecular weight are values measured by gel permeation chromatography (GPC) under the following conditions.
Solvent (eluant): tetrahydrofuran (THF)
Device name: TOSOH HLC-8320GPC
Columns: three columns of TOSOH TSKgel Super HZM-H (4.6 mm×15 cm) linked to each other in use
Column temperature: 40° C.
Sample Concentration: 0.1% by mass
Flow Rate: 1.0 ml/min
Calibration curve: TSK standard polystyrene (manufactured by TOSOH Corporation), calibration curves of 7 samples with Mw of 2,800,000 to 1,050 (Mw/Mn=1.03 to 1.06) are used

In a case where the polymerizable compound has the repeating unit having a photo-aligned group, polymerizable compounds described in WO2019/225632A and polymerizable compounds described in WO2020/179864A can also be suitably used.

A content of the polymerizable compound is preferably 50% to 99.9% by mass, more preferably 60% to 99% by mass, still more preferably 70% to 99% by mass, particularly preferably 80% to 99% by mass, and most preferably 85% to 99% by mass with respect to the total solid content of the composition for forming an alignment film.

The polymerizable compound may be used alone or in combination of two or more kinds thereof.

In a case where two or more kinds of the polymerizable compounds are used, the total amount thereof is preferably within the above-described preferred content range.

### [Solvent]

The composition for forming an alignment film may contain a solvent.

Examples of the solvent include water and an organic solvent.

As the organic solvent, an organic solvent which is miscible with water at an arbitrary ratio is preferable.

It is preferable that the solvent is selected such that the components contained in the particles do not dissolve.

Examples of the organic solvent include an alcohol-based solvent, a glycol-based solvent, a glycol ether-based solvent, a ketone-based solvent, an amide-based solvent, and a sulfur-containing solvent.

Examples of the alcohol-based solvent include methanol, ethanol, propanol, isopropyl alcohol, 1-butanol, 2-butanol, isobutyl alcohol, and tert-butyl alcohol.

Examples of the glycol-based solvent include ethylene glycol, propylene glycol, diethylene glycol, dipropylene glycol, triethylene glycol, and tetraethylene glycol.

Examples of the glycol ether-based solvent include glycol monoether.

Examples of the glycol monoether include ethylene glycol monomethyl ether, ethylene glycol monoethyl ether, ethylene glycol mono-n-propyl ether, ethylene glycol monoisopropyl ether, ethylene glycol mono-n-butyl ether, diethylene glycol monomethyl ether, diethylene glycol monoethyl ether, diethylene glycol monobutyl ether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

Examples of the ketone-based solvent include acetone, methyl ethyl ketone, methyl isobutyl ketone, and cyclohexanone.

Examples of the amide-based solvent include N,N-dimethylformamide, 1-methyl-2-pyrrolidone, 2-pyrrolidinone, 1,3-dimethyl-2-imidazolidinone, formamide, N-methylformamide, acetamide, N-methylacetamide, N,N-dimethylacetamide, N-methylpropanamide, and hexamethylphosphoric triamide.

Examples of the sulfur-containing solvent include dimethyl sulfone, dimethyl sulfoxide, and sulfolane.

A content of the solvent is preferably 60% to 99.9% by mass, more preferably 70% to 99% by mass, and still more preferably 80% to 99% by mass with respect to the total mass of the composition for forming an alignment film.

The solvent may be used alone or in combination of two or more kinds thereof.

In a case where two or more kinds of the solvents are used, the total amount thereof is preferably within the above-described preferred content range.

### [Polymerization Initiator]

The composition for forming an alignment film may contain a polymerization initiator.

The polymerization initiator is selected according to the type of polymerization reaction, and examples thereof include a thermal polymerization initiator and a photopolymerization initiator.

Examples of the thermal polymerization initiator include an azo-based compound and a peroxide-based compound.

Examples of the photopolymerization initiator include an α-carbonyl compound, acyloin ether, an α-hydrocarbon-substituted aromatic acyloin compound, a polynuclear quinone compound, and a combination of a triarylimidazole dimer and p-aminophenyl ketone.

In a case where the composition for forming an alignment film contains a polymerization initiator, a content of the polymerization initiator is preferably 0.01% to 30% by mass and more preferably 0.5% to 20% by mass with respect to the total solid content of the composition for forming an alignment film.

### [Additive]

The composition for forming an alignment film may contain a component in addition to the above-described components, and examples of other components include additives such as a refractive index adjusting agent, an elastic modulus adjusting agent, a crosslinking agent, a filler, an adhesion improver, a leveling agent, a surfactant, and a plasticizer. Among these, it is also preferable to use a crosslinking agent, and it is preferable that a crosslinkable group included in the crosslinking agent can be reacted with the polymerizable group included the polymerizable compound of the composition for forming an alignment film.

### <Polarizing Plate>

The polarizing plate according to the embodiment of the present invention includes the above-described optical film and a polarizer.

The polarizing plate refers to a plate which converts unpolarized light into light in a certain polarization state; and specific examples thereof include a linearly polarizing plate, an elliptically polarizing plate, and a circularly polarizing plate. As the polarizing plate, a linearly polarizing plate or a circularly polarizing plate is preferable.

In a case where the optical film included in the polarizing plate according to the embodiment of the present invention is a λ/4 plate, the polarizing plate according to the embodiment of the present invention can be suitably used as a circularly polarizing plate.

In a case where the polarizing plate according to the embodiment of the present invention is used as a circularly polarizing plate, the optical film according to the embodiment of the present invention is used as a λ/4 plate, and an angle formed by a slow axis of the λ/4 plate and an absorption axis of the polarizer, which will be described later, is preferably 30° to 60°, more preferably 40° to 50°, still more preferably 42° to 48°, and particularly preferably 45°.

In addition, the polarizing plate according to the embodiment of the present invention can also be used as an optical compensation film for a liquid crystal display device in an in-plane-switching (IPS) mode or a fringe-field-switching (FFS) mode.

In a case where the polarizing plate according to the embodiment of the present invention is used as an optical compensation film for an IPS mode or FFS mode liquid crystal display device, it is preferable that the above-described optical film according to the embodiment of the present invention is used as a laminate of a positive A-plate and a positive C-plate, an angle formed by a slow axis of the positive A-plate and an absorption axis of the polarizer, which will be described later, are orthogonal or parallel; and specifically, it is more preferable that the angle formed by the slow axis of the positive A-plate and the absorption axis of the polarizer, which will be described later, is 0° to 5° or 850 to 95°.

Here, the “slow axis” of the λ/4 plate or the positive A-plate means a direction in which a refractive index in the plane of the λ/4 plate or the positive A-plate is maximum; and the “absorption axis” of the polarizer means a direction in which an absorbance is highest.

### [Polarizer]

The polarizer of the polarizing plate according to the embodiment of the present invention is not particularly limited as long as the polarizer is a member having a function of converting light into specific linearly polarized light, and a known absorptive type polarizer and reflective type polarizer in the related art can be used.

An iodine-based polarizer, a dye-based polarizer using a dichroic dye, a polyene-based polarizer, or the like is used as the absorptive type polarizer. The iodine-based polarizer and the dye-based polarizer include a coating type polarizer and a stretching type polarizer, and any one of these polarizers can be applied. However, a polarizer which is produced by allowing polyvinyl alcohol to adsorb iodine or a dichroic dye and performing stretching is preferable.

In addition, examples of the method of obtaining a polarizer by stretching and dyeing a laminated film in which a polyvinyl alcohol layer is formed on a substrate include methods described in JP5143918B, JP5048120B, JP4691205B, JP4751481B, and JP4751486B, and known techniques related to these polarizers can also be preferably used.

A polarizer in which thin films having different birefringence are laminated, a wire grid type polarizer, a polarizer in which a cholesteric liquid crystal having a selective reflection range and a ¼ wavelength plate are combined, or the like is used as the reflective type polarizer.

Among these, as the polarizer, from the viewpoint of more excellent adhesiveness, a polarizer containing a polyvinyl alcohol-based resin (polymer including —CH₂—CHOH— as a repeating unit; in particular, at least one selected from the group consisting of polyvinyl alcohol and an ethylene-vinyl alcohol copolymer) is preferable.

A thickness of the polarizer is not particularly limited, but is preferably 3 to 60 μm, more preferably 3 to 30 μm, and still more preferably 3 to 10 μm.

The polarizing plate according to the embodiment of the present invention may have a configuration other than the polarizer and the optical film.

Examples of other configurations include a retardation layer, an optical compensation film, a pressure-sensitive adhesive layer, an adhesive layer, a refractive index adjusting layer, a barrier layer, and a tint adjusting layer.

### <Manufacturing Method of Polarizing Plate>

The manufacturing method of a polarizing plate according to the embodiment of the present invention includes:
a step of applying the above-described composition for forming an alignment film onto a support to form a first coating film, and subjecting the first coating film to an alignment treatment (hereinafter, also referred to as “step 1”);
a step of applying a composition containing a liquid crystal compound onto the first coating film subjected to the alignment treatment to form a second coating film (hereinafter, also referred to as “step 2”);
a step of subjecting the first coating film and the second coating film to a curing treatment for forming an alignment film and an optically anisotropic layer to form a laminate including the support, the alignment film, and the optically anisotropic layer (hereinafter, also referred to as “step 3”); and
a step of bonding the laminate to a polarizer such that the optically anisotropic layer and the polarizer face each other, and peeling off the support from the obtained bonded body to obtain a polarizing plate including the polarizer, the optically anisotropic layer, and the alignment film (hereinafter, also referred to as “step 4”).

Hereinafter, the respective steps will be described.

### [Step 1]

In the step 1, a composition for forming an alignment film is applied onto a support to form a first coating film, and the first coating film is subjected to an alignment treatment.

The composition for forming an alignment film is as described above.

Examples of the support include a glass substrate and a polymer film.

Examples of a material of the polymer film include cellulose-based polymers; acrylic polymers such as polymethyl methacrylate; thermoplastic norbornene-based polymers; polycarbonate-based polymers; polyester-based polymers such as polyethylene terephthalate and polyethylene naphthalate; styrene-based polymers such as polystyrene and an acrylonitrile-styrene copolymer; polyolefin-based polymers such as polyethylene, polypropylene, and an ethylene-propylene copolymer; vinyl chloride-based polymers; amide-based polymers such as nylon and aromatic polyamide; imide-based polymers; sulfone-based polymers; polyether sulfone-based polymers; polyether ether ketone-based polymers; polyphenylene sulfide-based polymers; vinylidene chloride-based polymers; vinyl alcohol-based polymers; vinyl butyral-based polymers; arylate-based polymers; polyoxymethylene-based polymers; epoxy-based polymers; and polymers obtained by mixing these polymers.

The support may be peeled off after the polarizing plate is formed.

A thickness of the support is not particularly limited, but is preferably 5 to 200 μm, more preferably 10 to 100 μm, and still more preferably 20 to 90 μm.

A method of applying the composition for forming an alignment film is not particularly limited, and a known method may be used. Examples of the applying method include an air knife coating method, a curtain coating method, a roller coating method, a wire bar coating method, a gravure coating method, and a die coating method.

The alignment treatment on the first coating film may be selected depending on the type of the composition for forming an alignment film.

In a case where the alignment film formed of the composition for forming an alignment film is a photo-alignment film, examples of the alignment treatment include a light irradiating treatment. Examples of the light irradiating treatment include an ultraviolet irradiating treatment. Ultraviolet rays to be radiated in the ultraviolet irradiating treatment may be non-polarized ultraviolet rays or linearly polarized ultraviolet rays. In addition, the non-polarized ultraviolet rays and the linearly polarized ultraviolet rays may be used in combination.

In a case where the alignment film formed of the composition for forming an alignment film is not a photo-alignment film, examples of the alignment treatment include a rubbing treatment. As the rubbing treatment, a known method can be adopted, and examples thereof include a method of rubbing a surface of the first coating film with paper or cloth in a certain direction multiple times.

The direction of the rubbing treatment can be appropriately set depending on a direction in which the liquid crystal compound is desired to be aligned.

Before performing the alignment treatment on the first coating film, a treatment of removing the solvent contained in the composition for forming an alignment film may be performed. Examples of the method of removing the solvent include a heating treatment. A temperature of the heating treatment can be appropriately set depending on the type of the solvent contained in the composition for forming an alignment film, and the like, but is preferably 50° C. to 150° C.

### [Step 2]

In the step 2, a composition containing a liquid crystal compound (liquid crystal composition) is applied onto the above-described first coating film subjected to the alignment treatment to form a second coating film.

The liquid crystal composition is as described above.

A method of applying the liquid crystal composition is not particularly limited, and a known method can be adopted. For example, the methods described in the method of applying the composition for forming an alignment film can be adopted.

After the application of the liquid crystal composition, the solvent contained in the liquid crystal composition may be removed. The removal method is not particularly limited, and examples thereof include natural drying, decompression treatment, and heating. A heating temperature may be appropriately set depending on the type of the solvent, and examples thereof include 40° C. to 200° C.

A treatment of aligning the liquid crystal compound contained in the second coating film may be performed between the step 2 and the step 3 described later.

The treatment of aligning the liquid crystal compound is not particularly limited, and a known method can be used.

Examples of the method of aligning the liquid crystal compound include a method of applying an electric field to the second coating film and a method of heating the second coating film to perform a phase transition to a liquid crystal phase; and the heating method is preferable.

A heating temperature may be selected depending on the liquid crystal compound contained in the second coating film, and examples thereof include 40° C. to 200° C.; and 90° C. to 150° C. is preferable. The treatment of aligning the liquid crystal compound may be performed at the same time as the heating performed in a case of removing the solvent which can be contained in the second coating film.

In a case where the heating is performed, it is also preferable to perform, after the heating, a treatment of setting the temperature of the second coating film to be lower than that of the alignment treatment, in order to stabilize the alignment direction of the liquid crystal compound. The above-described temperature is preferably 40° C. to 100° C. and more preferably 40° C. to 80° C.

In addition, in a case where the second coating film contains a chiral agent, the second coating film may be irradiated with ultraviolet rays in order to change the helical twisting power of the chiral agent. It is preferable that the irradiation with ultraviolet rays is carried out in an atmosphere containing oxygen.

After the irradiation with ultraviolet rays, the heating treatment may be performed again.

The above-described ultraviolet rays to be radiated mainly include electromagnetic waves having a wavelength of 200 to 400 nm, and preferably mainly include electromagnetic waves having a wavelength of 300 to 400 nm. A light source of ultraviolet rays is not particularly limited and a known light source can be used, and ultraviolet rays including any wavelength range may be radiated using a filter or the like. Examples of the light source of ultraviolet rays include a high-pressure mercury lamp, a metal halide lamp, and a light emitting diode (LED).

An irradiation amount of the ultraviolet rays may be appropriately set, but is preferably 5 to 100 mJ/cm² and more preferably 10 to 50 mJ/cm².

### [Step 3]

In the step 3, the above-described first coating film and the above-described second coating film are subjected to a curing treatment to form an alignment film and an optically anisotropic layer, and thus a laminate including the support, the alignment film, and the optically anisotropic layer is formed.

As the curing treatment, an ultraviolet irradiating treatment is preferable.

The ultraviolet irradiating treatment is preferably performed in an atmosphere with a low oxygen concentration. The oxygen concentration in the atmosphere in which the ultraviolet irradiating treatment is performed is preferably 2,000 ppm by volume or less, more preferably 1,000 ppm by volume or less, and still more preferably 500 ppm by volume or less. The lower limit of the oxygen concentration is, for example, 0 ppm by volume or more.

It is also preferable that the ultraviolet irradiating treatment is performed in a temperature-controlled state. The temperature of the first coating film and the second coating film during the ultraviolet irradiating treatment can be appropriately adjusted according to the components contained in the first coating film and the second coating film, but is preferably 150° C. to 120° C. and more preferably 60° C. to 100° C.

### [Step 4]

In the step 4, the above-described laminate is bonded to a polarizer such that the optically anisotropic layer and the polarizer face each other, and the support is peeled off from the obtained bonded body to obtain a polarizing plate including the polarizer, the optically anisotropic layer, and the alignment film.

Examples of the polarizer include the above-described polarizer.

A method of bonding the polarizer and the laminate is not particularly limited, and examples thereof include a method of applying a pressure sensitive adhesive or an adhesive onto a surface of the laminate on the optically anisotropic layer side or onto a surface of the polarizer, and bonding the polarizer and the laminate.

As the pressure sensitive adhesive and the adhesive, known agents can be used.

The support can be peeled off by a known method.

### <Image Display Apparatus>

The polarizing plate according to the embodiment of the present invention can be applied to, for example, an image display apparatus.

The display element which is used in the image display apparatus is not particularly limited, and examples thereof include a liquid crystal cell, an organic electroluminescence (hereinafter, abbreviated as “EL”) display panel, and a plasma display panel.

Among these, a liquid crystal cell or an organic EL display panel is preferable. That is, the image display apparatus to which the polarizing plate according to the embodiment of the present invention is applied is preferably a liquid crystal display device using a liquid crystal cell as a display element or an organic EL display device using an organic EL display panel as a display element.

The liquid crystal cell which is used in the liquid crystal display device is preferably a vertical alignment (VA) mode, an optically compensated bend (OCB) mode, an in-plane-switching (IPS) mode, a fringe-field-switching (FFS) mode, or a twisted nematic (TN) mode, but the liquid crystal cell is not limited thereto.

As the liquid crystal display device which is an example of the image display apparatus according to the present invention, for example, it is preferable to have a polarizer, the optical film according to the embodiment of the present invention, and a liquid crystal cell in this order from a viewing side.

Suitable examples of the organic EL display device which is an example of the image display apparatus according to the present invention include an aspect in which a polarizer, the optical film according to the embodiment of the present invention, and an organic EL display panel are provided in this order from the visual side.

The organic EL display panel is a member in which a light emitting layer or a plurality of organic compound thin films including a light emitting layer is formed between a pair of electrodes of an anode and a cathode; and in addition to the light emitting layer, a hole injection layer, a hole transport layer, an electron injection layer, an electron transport layer, a protective layer, and the like may be provided, and each of these layers may have a different function. Various materials can be used to form the respective layers.

### EXAMPLES

Hereinafter, the present invention will be described in more detail with reference to Examples.

The materials, the amounts of materials used, the proportions, the treatment details, the treatment procedure, and the like shown in Examples below may be modified as appropriate as long as the modifications do not depart from the spirit of the present invention. Therefore, the scope of the present invention should not be construed as being limited to Examples shown below.

### <Production of Optical Film>

Hereinafter, a method of producing an optical film with a support, used in Example 1, will be described.

### [Production of Cellulose Acylate Film (Support)]

The following composition was put into a mixing tank, stirred, and heated at 90° C. for 10 minutes. Thereafter, the obtained composition was filtered through a filter paper having an average hole diameter of 34 μm and a sintered metal filter having an average hole diameter of 10 μm to prepare a dope. A concentration of solid contents of the dope was 23.5% by mass, an amount of a plasticizer (sugar ester compounds 1 and 2) added was a proportion with respect to cellulose acylate, and a solvent of the dope was methylene chloride/methanol/butanol=81/18/1 (mass ratio).

Cellulose acylate dope (1)

| | |
|---|---|
| Cellulose acylate (acetyl substitution degree: 2.86, | 100 parts by mass |
| viscosity average degree of polymerization: 310) | |
| Sugar ester compound 1 (represented by Chemical | 6.0 parts by mass |
| Formula (S4)) | |
| Sugar ester compound 2 (represented by Chemical | 2.0 parts by mass |
| Formula (S5)) | |
| Silica particle dispersion (AEROSIL R972, | 0.1 parts by mass |
| manufactured by Nippon Aerosil Co., Ltd.) | |
| Solvent (methylene chloride/methanol/butanol) | |

Sugar ester compounds 1 and 2

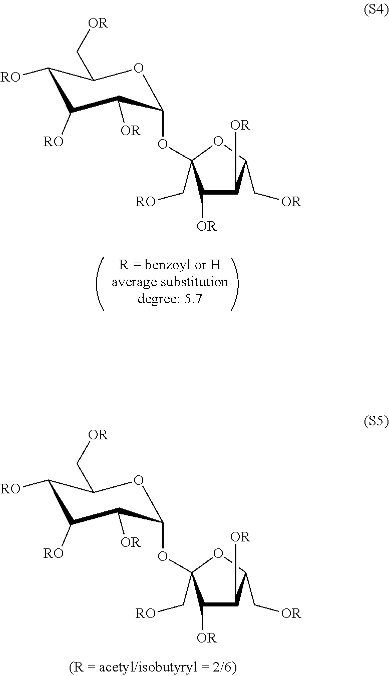

The dope produced by the above-described procedure was cast using a drum film forming machine. The dope was cast from a die such that the dope was in contact with a metal support cooled to 0° C., and then the obtained web (film) was stripped. The drum was made of SUS.

The web (film) obtained by casting was peeled off from the drum, and then dried in a tenter device for 20 minutes at 30° C. to 40° C. during film transport, and the tenter device transported the web by clipping both ends of the web. Subsequently, the web was post-dried by zone heating while being rolled. The obtained web was subjected to knurling to produce a winding support (1).

### (Alkali Saponification Treatment)

The above-described cellulose acylate film was passed through a dielectric heating roll at a temperature of 60° C. to raise a film surface temperature to 40° C. Thereafter, an alkaline solution having the following formulation was applied onto a band surface of the film at an application amount of 14 mL/m² using a bar coater, and then transported for 10 seconds under a steam type far-infrared heater manufactured by Noritake Company Limited, which was heated to 110° C. Subsequently, pure water was applied at 3 mL/m² using the same bar coater. Next, after repeating washing with water by a fountain coater and draining by an air knife three times, the film was transported to a drying zone at 70° C. for 10 seconds and dried to produce a cellulose acylate film subjected to an alkali saponification treatment.

Alkaline solution

| | | |
|---|---|---|
| Potassium hydroxide | 4.7 | parts by mass |
| Water | 15.8 | parts by mass |
| Isopropanol | 63.7 | parts by mass |
| Surfactant SF-1: C₁₄H₂₉O(CH₂CH₂O)₂₀H | 1.0 | part by mass |
| Propylene glycol | 14.8 | parts by mass |

### (Formation of First Coating Film)

A coating film (first coating film) was formed by continuously applying a composition 01 for forming an alignment film, having the following formulation, onto a surface of the cellulose acylate film, which had been subjected to the alkali saponification treatment, with a #14 wire bar. The first coating film was dried with hot air at 60° C. for 60 seconds and further dried with hot air at 100° C. for 120 seconds.

Composition O1 for forming alignment film

| | | |
|---|---|---|
| Polymerizable compound P1 | 100 | parts by mass |
| Ultraviolet absorber U1 shown below | 5.0 | parts by mass |
| Photopolymerization initiator shown below | 7.5 | parts by mass |
| Water | 2620 | parts by mass |
| Methanol | 873 | parts by mass |

Polymerizable compound P1 (in the formulae, the numerical value described in each repeating unit denotes the content (mol %) of each repetition unit with respect to all repeating units)

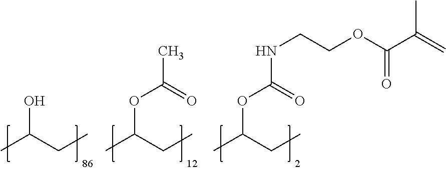

Ultraviolet absorber U1: Tinuvin (registered trademark) 479-DW (manufactured by BASF SE)

The ultraviolet absorber U1 is an aqueous dispersion of particles containing an ultraviolet absorber.

### Photopolymerization Initiator

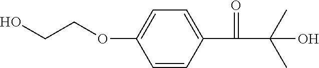 [SMILES: CC(C)(O)C(=O)c1ccc(OCCO)cc1]

### [Formation of Optically Anisotropic Layer]

The first coating film produced as described above was continuously subjected to a rubbing treatment. In this case, a longitudinal direction and a transport direction of the elongated film were parallel to each other, and an angle between the longitudinal direction (transport direction) of the film and a rotation axis of a rubbing roller was 78°. In a case where the longitudinal direction (transport direction) of the film was defined as 90° and the clockwise direction was represented by a positive value with reference to a width direction of the film as a reference (0°) in a case of being observed from the film side, the rotation axis of the rubbing roller was 12°. In other words, the position of the rotation axis of the rubbing roller is a position rotated by 78° counterclockwise with reference to the longitudinal direction of the film.

Using the cellulose acylate film subjected to the above-described rubbing treatment as a support, a liquid crystal composition L1 containing a rod-like liquid crystal compound, having the following formulation, was applied using a geeser coating machine to form a composition layer (second coating film). An absolute value of a weighted average helical twisting power of the chiral agent in the composition layer was 0.0 μm⁻¹.

Liquid crystal composition L1

| | | |
|---|---|---|
| Rod-like liquid crystal compound (A) shown below | 80 | parts by mass |
| Rod-like liquid crystal compound (B) shown below | 17 | parts by mass |
| Polymerizable compound (C) shown below | 3 | parts by mass |
| Ethylene oxide-modified trimethylolpropane triacrylate | 4 | parts by mass |
| (V#360, manufactured by Osaka Organic Chemical Industry Ltd.) | | |
| Photopolymerization initiator (Irgacure 819, manufactured by BASF SE) | 3 | parts by mass |
| Left-handed twisting chiral agent (L2) shown below | 0.47 | parts by mass |
| Right-handed twisting chiral agent (R2) shown below | 0.42 | parts by mass |
| Polymer (A) shown below | 0.08 | parts by mass |
| Methyl isobutyl ketone | 78 | parts by mass |
| Ethyl propionate | 78 | parts by mass |

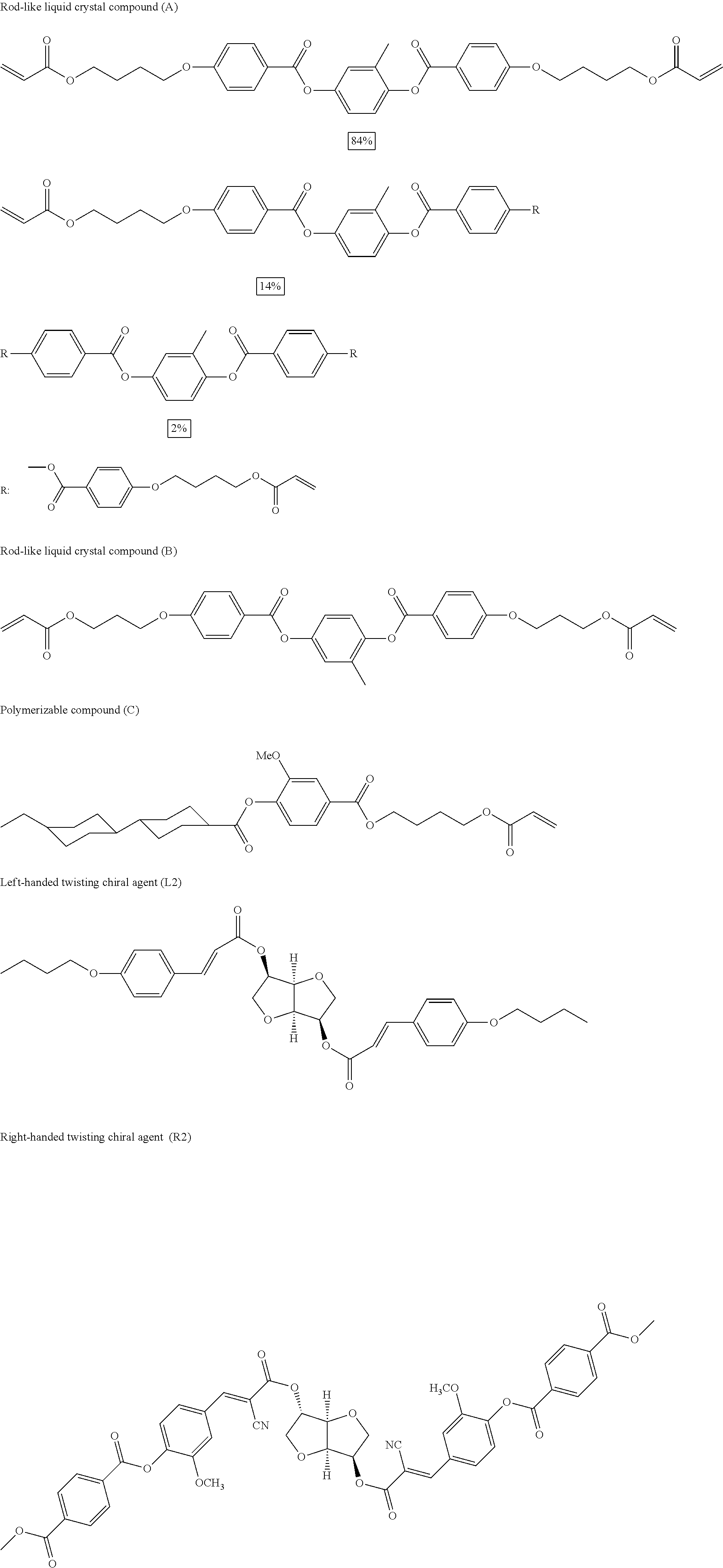

Polymer (A) (content of a repeating unit on the left side: 39% by mass, content of a repeating unit on the right side: 61% by mass)

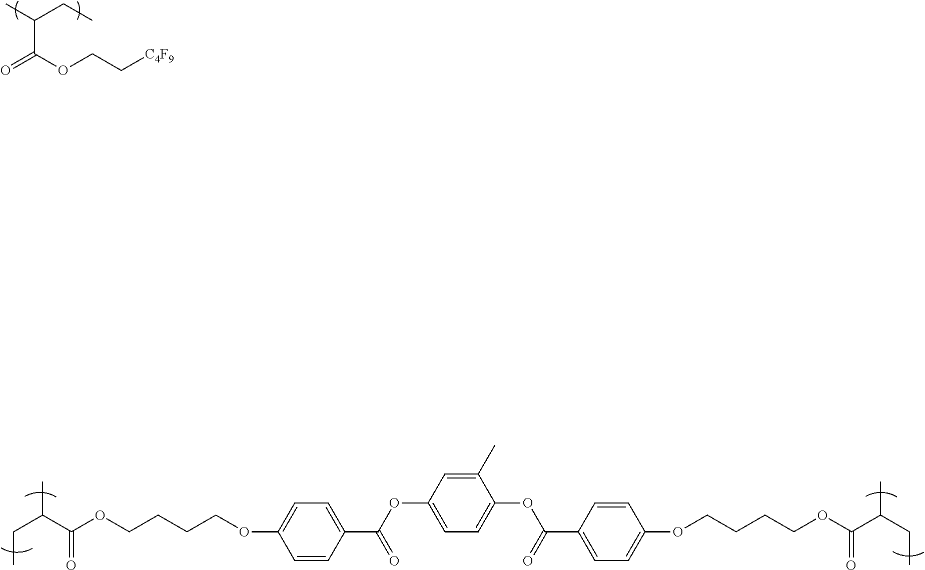

Next, the obtained composition layer was heated at 95° C. for 60 seconds. By the heating, the rod-like liquid crystal compound of the composition layer was aligned in a predetermined direction.

Thereafter, the composition layer was irradiated with ultraviolet rays (irradiation amount: 25 mJ/cm²) using an LED lamp (manufactured by AcroEdge Co., Ltd.) at 365 nm under a condition of 30° C. in the air containing oxygen (oxygen concentration: approximately 20% by volume).

Subsequently, the obtained composition layer was heated at 95° C. for 10 seconds.

Thereafter, nitrogen purging was performed, and the composition layer was irradiated with ultraviolet rays (irradiation amount: 500 mJ/cm²) using a metal halide lamp (manufactured by Eye Graphics Co., Ltd.) at 80° C. with an oxygen concentration of 100 ppm by volume to form an optically anisotropic layer in which the alignment state of the liquid crystal compound was fixed. In this manner, an optical film with a support, used in Example 1, was produced.

The optical film with a support of Example 1 produced by the above-described procedure was cut in parallel with the rubbing direction, and the optically anisotropic layer was observed from a cross-sectional direction with a polarization microscope. The optically anisotropic layer had a thickness of 2.7 μm, a region (second region) having a thickness of 1.3 μm on the support side of the optically anisotropic layer was homogeneously aligned without a twisted angle, and a region (first region) having a thickness of 1.4 μm on a side of the optically anisotropic layer opposite to the support was twistedly aligned with the liquid crystal compound.

Optical characteristics of the optical film with a support of Example 1 were determined using Axoscan of Axometrics, Inc. and analysis software (Multi-Layer Analysis) of Axometrics, Inc. A product (Δn2d2) of an in-plane refractive index difference Δn2 and a thickness d2 of the second region at a wavelength of 550 nm was 177 nm, a twisted angle of the liquid crystal compound was 0°, and an alignment axis angle of the liquid crystal compound with respect to the long longitudinal direction was −11° on the support side and −11° on the side in contact with the first region.

In addition, a product (Δn1d1) of an in-plane refractive index difference Δn1 and a thickness d1 of the first region at a wavelength of 550 nm was 180 nm, a twisted angle of the liquid crystal compound was 80°, and an alignment axis angle of the liquid crystal compound with respect to the long longitudinal direction was −11° on the side in contact with the second region and −91° on the air side.

Optical films with a support, used in Examples 2 to 5, were produced in the same manner as the optical film with a support of Example 1, except that the ultraviolet absorber U1 contained in the composition for forming an alignment film was changed to each of ultraviolet absorbers shown in the table later.

For Example 9, an optical film with a support was obtained in the same manner as in Example 4, except that the alignment film was formed without performing the alkali saponification treatment.

The addition amount of the ultraviolet absorber in each of Examples was adjusted to be the same as the content of the ultraviolet absorber U1 with respect to the content of the polymerizable compound P1 described above.

The ultraviolet absorbers used in each of Examples are shown below.

### (Ultraviolet Absorber U2)

Tinuvin (registered trademark) 477-DW (manufactured by BASF SE)

The ultraviolet absorber U2 is an aqueous dispersion of particles containing an ultraviolet absorber.

### (Ultraviolet Absorber U3)

SE-2915E (manufactured by Taisei Fine Chemical Co., Ltd.)

The ultraviolet absorber U3 is an aqueous dispersion of particles containing an ultraviolet absorber.

### (Ultraviolet Absorber U4)

The ultraviolet absorbing agent U4 was obtained by the following procedure.

First, a monomer M-1 having the following structure was synthesized with reference to WO2019/131572A.

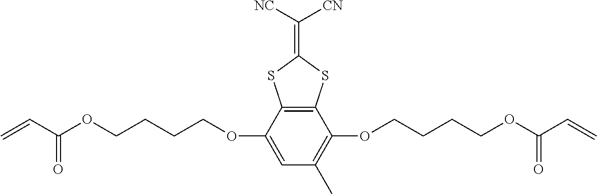 [SMILES: C=CC(=O)OCCCCOc1cc(C)c(OCCCCOC(=O)C=C)c2c1SC(=C(C#N)C#N)S2]

12.6 g of cyclohexanone and 12.6 g of 1-methoxy-2-propanol were charged into a 300 mL three-neck flask equipped with a stirring blade, a thermometer, a cooling pipe, and a nitrogen introduction pipe, and the mixture was heated to 120° C. under a nitrogen stream. A mixed solution of 3.75 g of the above-described monomer M-1, 1.25 g of acrylic acid, 0.74 g of a polymerization initiator V-601, and 25.2 g of cyclohexanone was added dropwise to the above-described contents over 120 minutes. After the reaction for 1 hour, a mixed solution of 0.8 g of a polymerization initiator V-601 and 1.7 g of cyclohexanone was added thereto, and the reaction was further carried out for 2 hours to obtain a solution containing a polymer having the following structure.

A weight-average molecular weight of the obtained polymer was 7,200, and it was confirmed by NMR that the target compound was obtained.

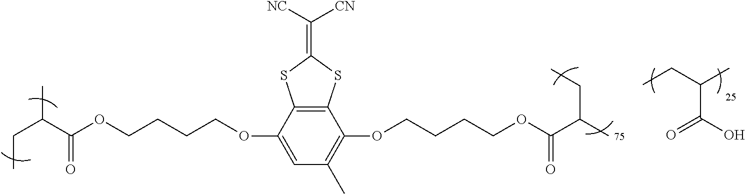

Next, 54.8 g of the obtained polymer solution was weighed in a reaction container, 31.8 g of isopropanol and 11.9 mL of a 1 mol/L NaOH aqueous solution were further added thereto, and the temperature in the reaction container was raised to 80° C. Next, 59.0 g of distilled water was added dropwise thereto at a rate of 20 mL/min, thereby dispersing the polymer in water. After the dispersion, the temperature in the reaction container was maintained at 80° C. for 2 hours under atmospheric pressure, maintained at 85° C. for 2 hours, and further maintained at 90° C. for 2 hours. After maintaining the temperature, the inside of the reaction container was depressurized, and a total of 74.9 g of isopropanol and distilled water was distilled off to obtain an aqueous dispersion of an ultraviolet absorber U4 having a concentration of solid contents (particle concentration) of 28.0% by mass.

Repeating units included in the polymer contained in the ultraviolet absorber U4 and ratios thereof are as follows.

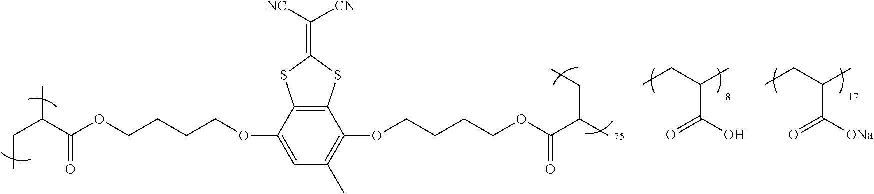

### (Ultraviolet Absorber U5)

12.6 g of cyclohexanone and 12.6 g of 1-methoxy-2-propanol were charged into a 300 mL three-neck flask equipped with a stirring blade, a thermometer, a cooling pipe, and a nitrogen introduction pipe, and the mixture was heated to 120° C. under a nitrogen stream. A mixed solution of 3.75 g of the above-described monomer M-1, 1.25 g of acrylic acid, 0.74 g of a polymerization initiator V-601, and 25.2 g of cyclohexanone was added dropwise thereto over 120 minutes. After the reaction for 1 hour, a mixed solution of 0.8 g of V-601 and 1.7 g of cyclohexanone was added thereto, and the reaction was further carried out for 2 hours.

After the reaction, the reaction solution was added dropwise to an excess of hexane, and the precipitated polymer solid was recovered and air-dried at 60° C. to obtain 4.46 g of a polymer solid. 0.50 g of glycidyl methacrylate, 0.24 g of tetrabutylammonium bromide, 0.2 g of methylhydroquinone, and 50 μmL of tetrahydrofuran were added to the obtained polymer solid for dissolving, and reacted at 80° C. for 8 hours.

A weight-average molecular weight of the polymer was 9,800, and it was confirmed by NMR that the target compound was obtained.

An aqueous dispersion of an ultraviolet absorber U5 was obtained by the same procedure as that for the ultraviolet absorber U4, using the obtained polymer solution.

Repeating units included in the polymer contained in the ultraviolet absorber U5 and ratios thereof are as follows.

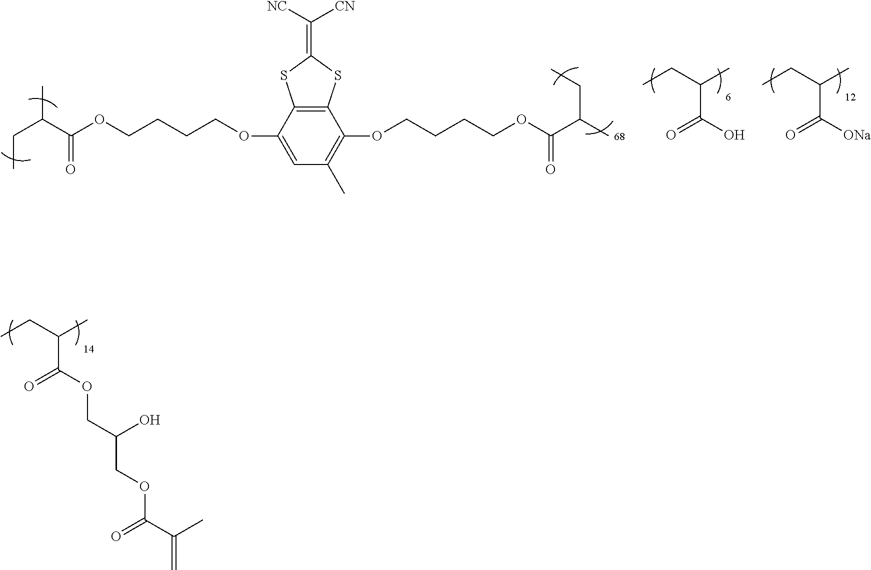

An optical film with a support, used in Example 6, was obtained in the same manner as the optical film with a support, used in Example 1, except that the formation of the first coating film was performed by the following procedure on a cellulose acylate film not subjected to the alkali saponification treatment.

### (Formation of First Coating Film)

A composition O6 for forming an alignment film was prepared by adding 100 parts by mass of a polymerizable compound P2, 0.80 parts by mass of a photoacid generator represented by the following structural formula, and 5.0 parts by mass of an ultraviolet absorber U6 to 1-methoxy-2-propanol (1,136 parts by mass).

### —Polymerizable Compound P2—

As the polymerizable compound P2, a polymerizable compound having the following repeating units was synthesized with reference to WO2019/225632A. The ratios of the following repeating units are mass ratios.

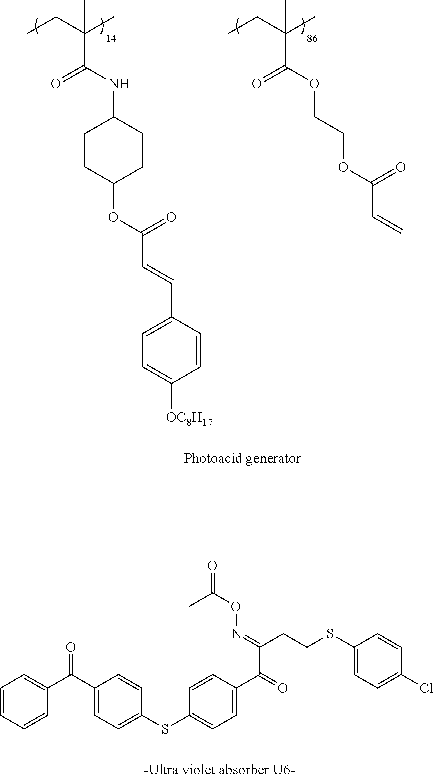

12.6 g of cyclohexanone and 12.6 g of 1-methoxy-2-propanol were charged into a 300 mL three-neck flask equipped with a stirring blade, a thermometer, a cooling pipe, and a nitrogen introduction pipe, and the mixture was heated to 120° C. under a nitrogen stream. A mixed solution of 5.00 g of the monomer M-1, 0.30 g of the polymerization initiator V-601, and 25.2 g of cyclohexanone was added dropwise thereto over 120 minutes. After the reaction for 1 hour, a mixed solution of 0.4 g of V-601 and 1.7 g of cyclohexanone was added thereto, and the reaction was further carried out for 2 hours to obtain a polymer having the following structure.

A weight-average molecular weight of the polymer was 110,000, and it was confirmed by NMR that the target compound was obtained.

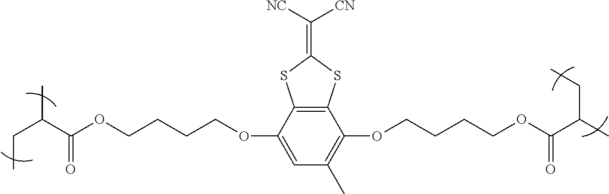

Next, 15 parts by mass of the above-described polymer was added to a solution obtained by dissolving 7 parts by mass of a dispersant (HINOACT series T-8000, manufactured by Kawaken Fine Chemicals Co., Ltd.) in 60 parts by mass of 1-methoxy-2-propanol. The solution containing the polymer was dispersed with a ball mill for 72 hours. After the dispersion, 75 parts by mass of 1-methoxy-2-propanol was added to the dispersion liquid, and the dispersion was further carried out with a ball mill for 5 hours. The obtained solution was diluted to a desired concentration of solid contents to obtain a dispersion liquid of the ultraviolet absorber U6.

The prepared composition O6 for forming an alignment film was applied onto one surface of the cellulose acylate film with a bar coater. After the application, the solvent was removed by drying on a hot plate at 123° C. for 62 seconds, and the coating film was irradiated with ultraviolet rays (300 mJ/cm², using an ultra-high pressure mercury lamp and a 365 nm band pass filter) to form a first coating film having a thickness of 0.5 μm. The obtained first coating film was irradiated with polarized ultraviolet rays (7.9 mJ/cm², using an ultra-high pressure mercury lamp) to form a photo-alignment film.

An optical film with a support, used in Example 7, was obtained in the same manner as the optical film with a support, used in Example 1, except that the formation of the first coating film was performed by the following procedure on a cellulose acylate film not subjected to the alkali saponification treatment.

### (Formation of First Coating Film)

A composition O7 for forming an alignment film was prepared by adding 100 parts by mass of a polymerizable compound P3, 0.80 parts by mass of a thermal acid generator represented by the following structural formula, and 5.0 parts by mass of the ultraviolet absorber U6 to 1-methoxy-2-propanol (1,136 parts by mass).

### —Polymerizable Compound P3—

A polymerizable compound having the following repeating units was synthesized with reference to WO2019/225632A. The ratios of the following repeating units are mass ratios.

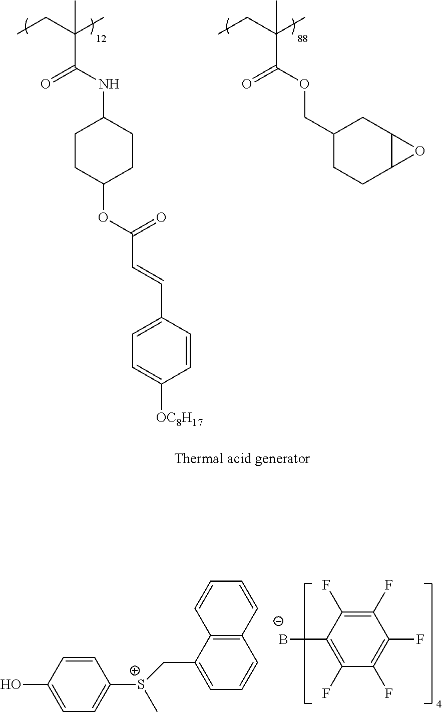

The prepared composition O7 for forming an alignment film was applied onto one surface of the cellulose acylate film with a bar coater. After the application, the coating film was dried on a hot plate at 80° C. for 5 minutes to remove the solvent, thereby forming a first coating film having a thickness of 0.5 μm. The obtained first coating film was irradiated with polarized ultraviolet rays (10 mJ/cm², using an ultra-high pressure mercury lamp) to form a photo-alignment film.

Optical films with a support, used in Examples 8 and 10, were produced in the same manner as the optical film with a support of Example 7, except that a composition for forming an alignment film, in which the ultraviolet absorber U6 was changed to each of ultraviolet absorbers shown in the table later, was used.

The addition amount of the ultraviolet absorbers in Examples 8 and 10 was adjusted to be the same as the content of the ultraviolet absorber U6 with respect to the content of the polymerizable compound P3 described above.

### (Ultraviolet Absorber U7)

A dispersion liquid of an ultraviolet absorber U7 was obtained by the same procedure as that for the ultraviolet absorber U6, except that the first dispersion time with a ball mill was 48 hours in the procedure for obtaining the dispersion liquid of the ultraviolet absorber U6.

### (Ultraviolet Absorber U8)

25 g of cyclohexanone was charged into a 300 μmL three-neck flask equipped with a stirring blade, a thermometer, a cooling pipe, and a nitrogen introduction pipe, and the solvent was heated to 120° C. under a nitrogen stream. A mixed solution of 4.75 g of the above-described monomer M-1, 0.25 g of CYCLOMER M100 (manufactured by Daicel Corporation), 0.30 g of a polymerization initiator V-601, and 25.2 g of cyclohexanone was added dropwise thereto over 120 minutes. After the reaction for 1 hour, a mixed solution of 0.4 g of V-601 and 1.7 g of cyclohexanone was added thereto, and the reaction was further carried out for 2 hours to obtain a polymer having the following structure.

A weight-average molecular weight of the polymer was 12,500, and it was confirmed by NMR that the target compound was obtained.

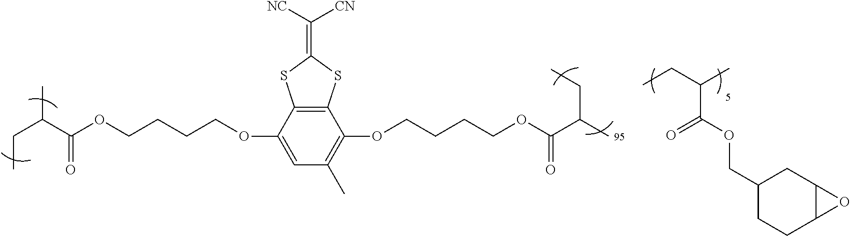

A dispersion of an ultraviolet absorber U8 was obtained by the same procedure as that for the ultraviolet absorber U6, using the obtained polymer solution.

An optical film with a support, used in Example 11, was obtained in the same manner as in Example 10, except that, in the formation of the optically anisotropic layer, a liquid crystal composition L2 shown below was used instead of the liquid crystal composition L1.

Liquid crystal composition L2

| | | |
|---|---|---|
| Rod-like liquid crystal compound (D) | 100 | parts by mass |
| shown below | | |
| Photocationic polymerization initiator | 6 | parts by mass |
| [CPI-100P (propylene carbonate solution), | | |
| manufactured by San-Apro Ltd.] | | |
| Left-handed twisting chiral agent (L2) | 0.47 | parts by mass |
| shown above | | |
| Right-handed twisting chiral agent (R2) | 0.42 | parts by mass |
| shown above | | |
| Polymer (A) shown above | 0.08 | parts by mass |
| Methyl isobutyl ketone | 78 | parts by mass |
| Ethyl propionate | 78 | parts by mass |

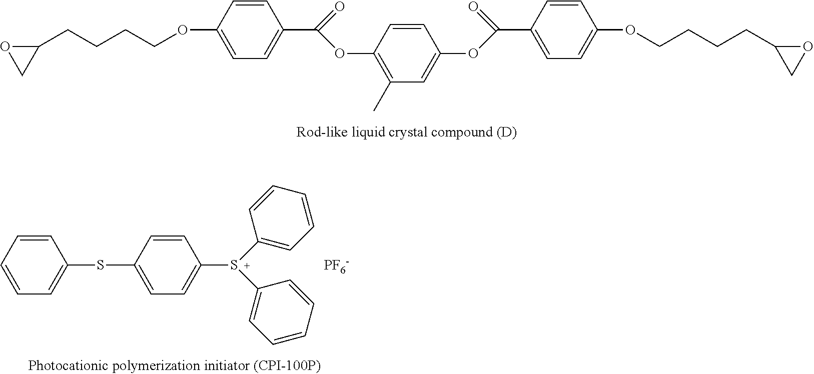

An optical film with a support, used in Example 12, was obtained in the same manner as in Example 10, except that the following polymerizable compound P4 was used instead of the polymerizable compound P3.

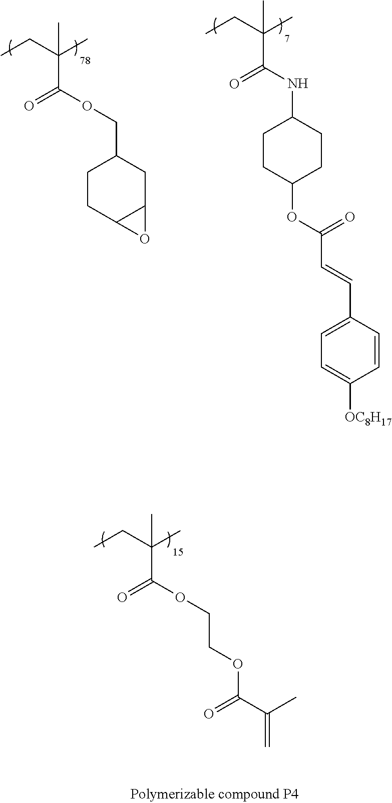

In addition, optical films with a support, used in Comparative Examples 1 to 3, were produced in the same manner as the optical film with a support of Example 1, except that the ultraviolet absorber U1 contained in the composition for forming an alignment film was changed to each of ultraviolet absorbers shown in the table later.

The addition amount of the ultraviolet absorber in Comparative Examples 1 to 3 was adjusted to be the same as the content of the ultraviolet absorber U1 with respect to the content of the polymerizable compound P1 described above.

The ultraviolet absorbers used in each of Comparative Examples are shown below.

### (Ultraviolet Absorber UC1)

A dispersion liquid of an ultraviolet absorber UC1 was obtained by the same procedure as that for the ultraviolet absorber U6, except that the first dispersion time with a ball mill was 6 hours in the procedure for obtaining the dispersion liquid of the ultraviolet absorber U6.

### (Ultraviolet Absorber UC2)

Tinuvin (registered trademark) 477 (manufactured by BASF SE)

An optical film with a support, used in Comparative Example 4, was produced in the same manner as the optical film with a support of Example 1, except that the polymerizable compound contained in the composition for forming an alignment film was changed to a polymer PC1 (Kuraray Poval PVA-203).

An optical film with a support, used in Comparative Example 5, was produced in the same manner as the optical film with a support of Example 1, except that a composition for forming an alignment film, not containing the ultraviolet absorber U1, was used.

### <Evaluation>

The following evaluations were performed on each of the produced optical films with a support.

### [Aligning Properties]

Aligning properties of the optically anisotropic layer in the optical film with a support were evaluated using a polarization microscope. Specifically, the optically anisotropic layer in the optical film with a support was observed at a magnification of 50 times in a state in which the polarizer of the polarization microscope was installed to be crossed nicols. The observation was performed in 10 randomly selected visual fields (visual field size: 1715×1280 μm), and each visual field was classified into the following three categories.
I: no optical defects were observed.
II: some optical defects were observed, but it was at a level in which there was no problem in practical use.
III: many optical defects were observed, and it was a level in which there was a problem in practical use.

Based on the classification of the 10 observed visual fields, aligning properties were evaluated according to the following standard.
A: all 10 visual fields were I or II.
B: 10 visual fields included III, and the number of visual fields of III was 1 to 5.
C: 10 visual fields included III, and the number of visual fields of III was 6 to 10.

### [Adhesiveness]

A cross-cut 100 square test was performed on the optically anisotropic layer of the optical film with a support. For the optical film with a support of Example 9, the support was peeled off once from the alignment film, and the alignment film and the support were adhered to each other with an adhesive (manufactured by Toagosei Co., Ltd., Aron Alpha 221F) so as to face each other. As a pressure-sensitive adhesive tape used for the peeling test, CELLOTAPE (registered trademark) was used, and the peeling test was performed three times. After the peeling test, the number of squares in which an area of half or more was peeled off was counted, and the evaluation was performed according to the following standard.
AA: number of peeled squares was 0 or more and less than 5.
A: number of peeled squares was 5 or more and less than 10.
B: number of peeled squares was 10 or more and less than 30.
C: number of peeled squares was 30 or more and less than 50.
D: number of peeled squares was 50 or more.

In the cross-cut test, the support side of the portion where peeling occurred was cut with a microtome to expose the cross section, and the cross section was observed with a scanning electron microscope. As a result, in all optical films with a support, which were evaluated for the adhesiveness, the alignment film remained on the support side. Therefore, it can be said that the peeling position in a case where peeling occurred in the evaluation of the adhesiveness was not between the support and the alignment film.

### [Ultraviolet Absorbability]

Ultraviolet absorbability of the optical film with a support was evaluated using a spectrophotometer. Specifically, a transmittance of the optical film with a support at a wavelength of 380 nm was measured using a spectrophotometer UV3150 (manufactured by Shimadzu Corporation). Based on the obtained transmittance, the ultraviolet absorbability was evaluated according to the following standard.
A: less than 65%
B: 65% or more and less than 75%
C: 75% or more and less than 85%
D: 85% or more

### <Result>

Table 1 shows the composition for forming an alignment film, used in the production of each optical film with a support, and the evaluation results of the produced optical film with a support.

In Table 1, the particle diameter indicates a value obtained by the method described above.

In Table 1, the column of “Maximal absorption wavelength” of the ultraviolet absorber is described in the following classification based on the maximal absorption wavelength of the ultraviolet absorber evaluated by the above-described method.
A: maximal absorption wavelength was 360 to 400 nm.
B: maximal absorption wavelength was 320 nm or more and less than 360 nm.

TABLE 1

| | Composition for forming alignment film | | | | | | | | |
|---|---|---|---|---|---|---|---|---|---|
| | | Ultraviolet absorber | | | | | | | |
| | | | Maximal | | | | | | |
| | | | absorption | Particle | | | Evaluation | | |
| | Polymerizable | | wavelength | diameter | Polymerizable | Saponification | Aligning | Ultraviolet | |
| | compound | Type | [nm] | [nm] | group | treatment | properties | absorbability | Adhesiveness |
| Example 1 | P1 | U1 | B | 120 | — | Y | A | C | A |
| Example 2 | P1 | U2 | B | 130 | — | Y | A | B | A |
| Example 3 | P1 | U3 | B | 110 | — | Y | A | C | A |
| Example 4 | P1 | U4 | A | 150 | — | Y | A | A | A |
| Example 5 | P1 | U5 | A | 150 | Radical | Y | A | A | AA |
| Example 6 | P2 | U6 | A | 150 | — | N | A | A | A |
| Example 7 | P3 | U6 | A | 150 | — | N | A | A | C |
| Example 8 | P3 | U7 | A | 450 | — | N | B | A | C |
| Example 9 | P1 | U4 | A | 150 | — | N | A | A | A |
| Example 10 | P3 | U8 | A | 150 | Cationic | N | A | A | B |
| Example 11 | P3 | U8 | A | 150 | Cationic | N | A | A | AA |
| Example 12 | P4 | U8 | A | 150 | Cationic | N | A | A | AA |
| Comparative | P1 | UC1 | A | 800 | — | Y | C | A | A |
| Example 1 | | | | | | | | | |
| Comparative | P2 | UC2 | B | — | — | Y | A | B | D |
| Example 2 | | | | | | | | | |
| Comparative | P1 | UC2 | B | — | — | Y | C | B | D |
| Example 3 | | | | | | | | | |
| Comparative | PC1 | U4 | A | 150 | — | Y | A | A | D |
| Example 4 | | | | | | | | | |
| Comparative | P1 | — | — | — | — | Y | A | D | A |
| Example 5 | | | | | | | | | |

From the results in Table 1, it was found that the optical film according to the embodiment of the present invention was excellent in ultraviolet absorbability, excellent in aligning properties of the liquid crystal compound in the optically anisotropic layer, and excellent in adhesiveness between the alignment film and the optically anisotropic layer.

On the other hand, in Comparative Example 1 in which the particle diameter of the particles was 500 nm or more, the aligning properties of the liquid crystal compound in the optically anisotropic layer were deteriorated. In addition, in Comparative Examples 2 and 3 in which a non-particulate ultraviolet absorber was used, the adhesiveness was deteriorated. In addition, in Comparative Example 4 in which a compound having no polymerizable group was used, the adhesiveness was deteriorated. In addition, in Comparative Example 5 in which the ultraviolet absorber was not used, the ultraviolet absorbability was deteriorated.

From the comparison between Example 5 and Example 4, and the comparison between Example 10 and Example 7, it was found that, in a case where the particles had a polymerizable group, and both the polymerizable group of the particles and the polymerizable group of the polymerizable compound were radically polymerizable groups, or both the polymerizable group of the particles and the polymerizable group of the polymerizable compound were cationically polymerizable groups, the adhesiveness was more excellent.

From the comparison between Examples 11 and 12 and Example 10, it was found that, in a case where the liquid crystal compound had a polymerizable group, and both the polymerizable group of the liquid crystal compound and the polymerizable group of the polymerizable compound were radically polymerizable groups, or both the polymerizable group of the liquid crystal compound and the polymerizable group of the polymerizable compound were cationically polymerizable groups, the adhesiveness was more excellent.

What is claimed is:

1. An optical film comprising:
an alignment film; and
an optically anisotropic layer disposed adjacent to the alignment film,
wherein the optically anisotropic layer is formed of a composition containing a liquid crystal compound,
the alignment film contains particles containing an ultraviolet absorber and a cured substance of a polymerizable compound having a polymerizable group,
an average particle diameter of the particles is 500 nm or less, and
a maximal absorption wavelength of the ultraviolet absorber is positioned in a range of 320 to 400 nm.

2. The optical film according to claim 1,
wherein the maximal absorption wavelength is positioned in a range of 360 to 400 nm.

3. The optical film according to claim 1,
wherein the ultraviolet absorber is a benzodithiol-based compound.

4. The optical film according to claim 1,
wherein the liquid crystal compound has a polymerizable group, and
both the polymerizable group of the liquid crystal compound and the polymerizable group of the polymerizable compound are radically polymerizable groups, or
both the polymerizable group of the liquid crystal compound and the polymerizable group of the polymerizable compound are cationically polymerizable groups.

5. The optical film according to claim 1,
wherein the particles have a polymerizable group, and
both the polymerizable group of the particles and the polymerizable group of the polymerizable compound are radically polymerizable groups, or
both the polymerizable group of the particles and the polymerizable group of the polymerizable compound are cationically polymerizable groups.

6. A polarizing plate comprising:
the optical film according to claim 1; and
a polarizer.

7. A composition for forming an alignment film, comprising:
particles containing an ultraviolet absorber; and
a polymerizable compound having a polymerizable group,
wherein an average particle diameter of the particles is 500 nm or less, and
a maximal absorption wavelength of the ultraviolet absorber is positioned in a range of 320 to 400 nm.

8. The composition for forming an alignment film according to claim 7,
wherein the maximal absorption wavelength is positioned in a range of 360 to 400 nm.

9. The optical film according to claim 7,
wherein the ultraviolet absorber is a benzodithiol-based compound.

10. The composition for forming an alignment film according to claim 7,
wherein the particles have a polymerizable group, and
both the polymerizable group of the particles and the polymerizable group of the polymerizable compound are radically polymerizable groups, or
both the polymerizable group of the particles and the polymerizable group of the polymerizable compound are cationically polymerizable groups.

11. A manufacturing method of a polarizing plate, comprising:
a step of applying the composition for forming an alignment film according to claim 7 onto a support to form a first coating film, and subjecting the first coating film to an alignment treatment;
a step of applying a composition containing a liquid crystal compound onto the first coating film subjected to the alignment treatment to form a second coating film;
a step of subjecting the first coating film and the second coating film to a curing treatment for forming an alignment film and an optically anisotropic layer to form a laminate including the support, the alignment film, and the optically anisotropic layer; and
a step of bonding the laminate to a polarizer such that the optically anisotropic layer and the polarizer face each other, and peeling off the support from the obtained bonded body to obtain a polarizing plate including the polarizer, the optically anisotropic layer, and the alignment film.

12. A manufacturing method of a polarizing plate, comprising:
a step of applying the composition for forming an alignment film according to claim 8 onto a support to form a first coating film, and subjecting the first coating film to an alignment treatment;
a step of applying a composition containing a liquid crystal compound onto the first coating film subjected to the alignment treatment to form a second coating film;
a step of subjecting the first coating film and the second coating film to a curing treatment for forming an alignment film and an optically anisotropic layer to form a laminate including the support, the alignment film, and the optically anisotropic layer; and
a step of bonding the laminate to a polarizer such that the optically anisotropic layer and the polarizer face each other, and peeling off the support from the obtained bonded body to obtain a polarizing plate including the polarizer, the optically anisotropic layer, and the alignment film.
